(19) United States
(12) Patent Application Publication
(10) Pub. No.: US 2024/0332034 A1
(43) Pub. Date: Oct. 3, 2024

(54) INTEGRATED CIRCUIT AND METHOD OF FORMING THE SAME

(71) Applicant: TAIWAN SEMICONDUCTOR MANUFACTURING COMPANY, LTD., Hsinchu (TW)

(72) Inventor: Shenggao LI, Hsinchu (TW)

(21) Appl. No.: 18/128,601

(22) Filed: Mar. 30, 2023

(51) Int. Cl. H01L 21/56; H01L 23/00; H01L 23/31; H01L 23/48; H01L 25/065

(52) U.S. Cl. CPC H01L 21/565; H01L 23/3121; H01L 23/481; H01L 24/05; H01L 24/16; H01L 24/32; H01L 25/0657; H01L 2224/0401; H01L 2224/05008; H01L 2224/16225; H01L 2224/32225; H01L 2225/06544

(57) ABSTRACT

A package structure includes a first integrated circuit (IC) chip, a first set of conductors on the first IC chip, a second set of conductors on the first IC chip, a first redistribution layer coupled to the first set of conductors and the second set of conductors; and a chip layer below the first redistribution layer. The chip layer includes a second IC chip electrically coupled to the first IC chip, a molding material, and a first through-via positioned in the molding material. The first set of conductors is a first set of micro-bumps having a first diameter or a first set of pillars having the first diameter. The second set of conductors is a second set of micro-bumps having a second diameter or a second set of pillars having the second diameter. The second diameter is greater than the first diameter.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductive layers of material over a semiconductor substrate, and patterning the various material layers using lithography to form circuit components and elements thereon. Many integrated circuits are typically manufactured on a single semiconductor wafer, and individual dies on the wafer are singulated by sawing between the integrated circuits along a scribe line. The individual dies are typically packaged separately, in multi-chip modules, or in other types of packaging, for example.

The semiconductor industry continues to improve the integration density of various electronic components (e.g., transistors, diodes, resistors, capacitors, etc.) by continual reductions in minimum feature size, which allow more components to be integrated into a given area. These smaller electronic components also require smaller packages that utilize less area than packages of the past, in some applications.

Three dimensional integrated circuits (3DICs) are a recent development in semiconductor packaging in which multiple semiconductor dies are stacked upon one another, such as package-on-package (POP) and system-in-package (SiP) packaging techniques. Some 3DICs are prepared by placing dies over dies on a semiconductor wafer level. 3DICs provide improved integration density and other advantages, such as faster speeds and higher bandwidth, because of the decreased length of interconnects between the stacked dies, as examples. However, there are many challenges related to 3DICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are corresponding diagrams of at least a portion of corresponding integrated circuit, in accordance with some embodiments.

FIGS. 2A-2B are diagrams of an integrated circuit, in accordance with some embodiments.

FIG. 3 is a top view of integrated circuit, in accordance with some embodiments.

FIG. 4 is a top view of integrated circuit, in accordance with some embodiments.

FIGS. 5A-5B are diagrams of an integrated circuit, in accordance with some embodiments.

FIG. 6 is a functional flow chart of a method of manufacturing an IC device, in accordance with some embodiments.

FIGS. 7A-7B are corresponding functional flow charts of method of manufacturing an IC device, in accordance with some embodiments.

FIGS. 8A-8K are cross-sectional views of IC device structures, in accordance with some embodiments.

### DETAILED DESCRIPTION

The following disclosure provides different embodiments, or examples, for implementing features of the provided subject matter. Specific examples of components, materials, values, steps, arrangements, or the like, are described below to simplify the present disclosure. These are, of course, merely examples and are not limiting. Other components, materials, values, steps, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above.” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In accordance with some embodiments, a package structure includes a first integrated circuit (IC) chip, a first set of conductors on the first IC chip, and a second set of conductors on the first IC chip.

In some embodiments, the package structure further includes a first redistribution layer coupled to the first set of conductors and the second set of conductors.

In some embodiments, the package structure further includes a chip layer below the first redistribution layer.

In some embodiments, the chip layer includes a second IC chip electrically coupled to the first IC chip.

In some embodiments, the chip layer further includes a molding material, and a first through-via positioned in the molding material.

In some embodiments, the first set of conductors is a first set of micro-bumps having a first diameter. In some embodiments, the second set of conductors is a second set of micro-bumps having a second diameter greater than the first diameter.

In some embodiments, by including the first set of conductors and the second set of conductors in the package structure, the package structure includes an array of micro-bumps that have different diameters thereby increasing a unit area of the second set of conductors compared to a unit area of the first set of conductors.

In some embodiments, by increasing the unit area of the second set of conductors with the second diameter thereby decreases the current density through the second set of conductors compared to other approaches, resulting in decreased power loss from at least the second set of conductors.

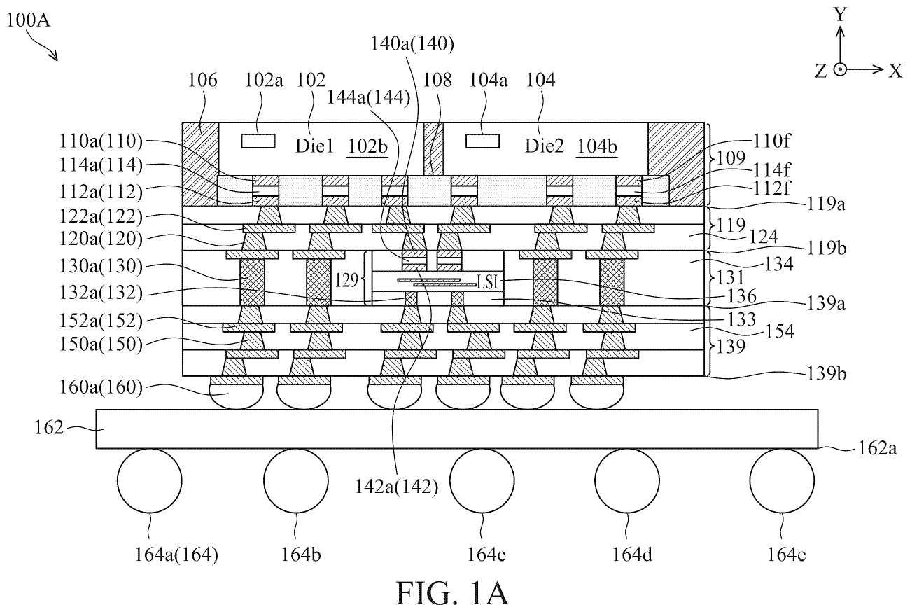

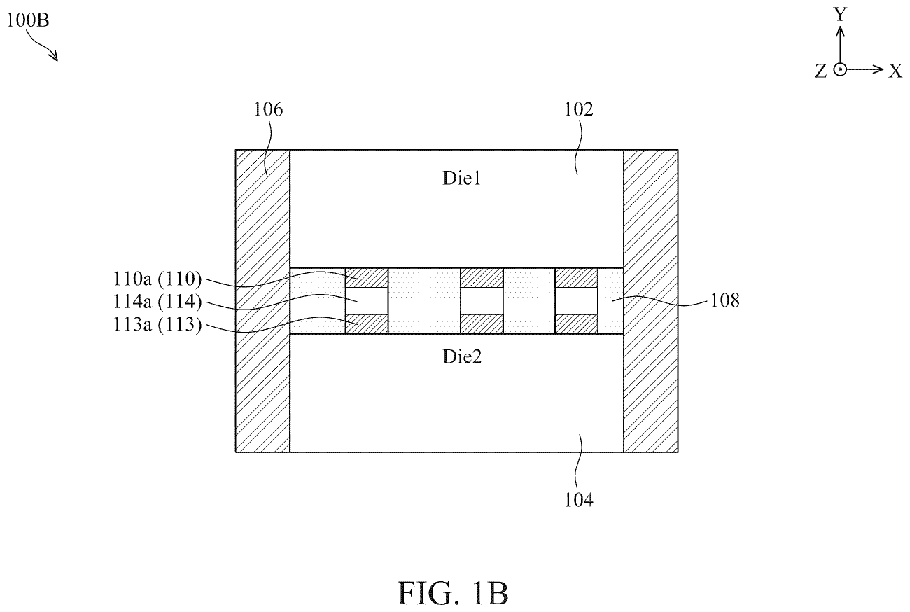

FIGS. 1A and 1B are corresponding diagrams of at least a portion of corresponding integrated circuit 100A and 100B, in accordance with some embodiments.

FIG. 1A is a cross-sectional view of an integrated circuit 100A, in accordance with some embodiments. In some embodiments, integrated circuit 100A is a horizontal 2.5D die attachment, and is also referred to as “an advanced package 2.5.” Other packaging types for integrated circuit 100A are within the scope of the present disclosure.

Integrated circuit 100A includes a semiconductor die 102 and a semiconductor die 104. Semiconductor die 102 includes one or more device regions 102a in a semiconductor substrate 102b. Semiconductor die 102 has a front side (not labelled) and a backside (not labelled). Semiconductor die 104 includes one or more device regions 104a in a semiconductor substrate 104b. Semiconductor die 104 has a front side (not labelled) and a backside not labelled.

Semiconductor substrate 102b has a top surface (not labelled) and a bottom surface (not labelled). In some embodiments, semiconductor substrate 102b is made of silicon or other semiconductor materials. In some embodiments, semiconductor substrate 102b includes other elementary semiconductor materials such as germanium. In some embodiments, semiconductor substrate 102b is made of a compound semiconductor, such as silicon carbide, gallium arsenic, indium arsenide, or indium phosphide. In some embodiments, semiconductor substrate 102b is made of an alloy semiconductor such as silicon germanium, silicon germanium carbide, gallium arsenic phosphide, or gallium indium phosphide. In some embodiments, semiconductor substrate 102b includes an epitaxial layer. For example, in some embodiments, semiconductor substrate 102b has an epitaxial layer overlying a bulk semiconductor. Other configurations, arrangements and materials of semiconductor substrate 102b are within the contemplated scope of the present disclosure.

The one or more device regions 102a are in the semiconductor die 102. In some embodiments, the one or more device regions 102a are formed in the front-side (not labelled) of semiconductor die 102 in a front-end-of-line (FEOL) process. In some embodiments, the one or more device regions 102a are formed in the back-side (not labelled) of semiconductor die 102 in an FEOL process. In some embodiments, the one or more device regions 102a include at least one transistor. In some embodiments, the one or more device regions 102a include at least one N-type metal-oxide semiconductor (NMOS) transistor and/or at least one P-type metal-oxide semiconductor (PMOS) transistor. In some embodiments, no devices are formed in the front side (not labelled) of semiconductor die 102. In some embodiments, the one or more devices 102a are formed in the backside (not labelled) of semiconductor die 102. In some embodiments, no devices are formed in the backside (not labelled) of semiconductor die 102.

In some embodiments, the one or more device regions 102a includes various NMOS and/or PMOS devices, such as transistors, memories, or processors, and the like, interconnected to perform one or more functions. In some embodiments, the one or more device regions 102a include other devices, such as capacitors, resistors, diodes, photo-diodes, fuses, and the like in substrate 102b. In some embodiments, the functions of the devices include memory, processing, sensors, amplifiers, power distribution, input/output circuitry, or the like. The one or more device regions 102a are merely an example, and other devices may be included in the one or more device regions 102a. Other devices, configurations, arrangements and materials of the one or more device regions 102a are within the contemplated scope of the present disclosure.

Other configurations, arrangements and materials of semiconductor die 102 are within the contemplated scope of the present disclosure.

Integrated circuit 100A further includes a semiconductor die 104. In some embodiments, semiconductor die 104 is a variation of semiconductor die 102, and similar detailed description is therefore omitted.

Semiconductor die 104 includes one or more device regions 104a in a semiconductor substrate 104b. Semiconductor die 104 has a front side (not labelled) and a backside not labelled.

Semiconductor substrate 104b has a top surface (not labelled) and a bottom surface (not labelled). In some embodiments, semiconductor substrate 104b is made of silicon or other semiconductor materials. In some embodiments, semiconductor substrate 104b includes other elementary semiconductor materials such as germanium. In some embodiments, semiconductor substrate 104b is made of a compound semiconductor, such as silicon carbide, gallium arsenic, indium arsenide, or indium phosphide. In some embodiments, semiconductor substrate 104b is made of an alloy semiconductor such as silicon germanium, silicon germanium carbide, gallium arsenic phosphide, or gallium indium phosphide. In some embodiments, semiconductor substrate 104b includes an epitaxial layer. For example, in some embodiments, semiconductor substrate 104b has an epitaxial layer overlying a bulk semiconductor. Other configurations, arrangements and materials of semiconductor substrate 104b are within the contemplated scope of the present disclosure.

In some embodiments, the one or more device regions 104a are the same as the one or more device regions 102a.

The one or more device regions 104a are formed in the front-side (not labelled) of semiconductor die 104. In some embodiments, the one or more device regions 104a are formed in the front side (not labelled) of semiconductor die 104 in a FEOL process. In some embodiments, the one or more device regions 104a are formed in the back-side (not labelled) of semiconductor die 104 in an FEOL process. In some embodiments, the one or more device regions 104a include at least one transistor. In some embodiments, the one or more device regions 104a include at least one NMOS transistor and/or at least one PMOS transistors. In some embodiments, no devices are formed in the front side (not labelled) of semiconductor die 104. In some embodiments, the one or more devices 104a are formed in the backside (not labelled) of semiconductor die 104. In some embodiments, no devices are formed in the backside (not labelled) of semiconductor die 104. Other configurations, arrangements and materials of semiconductor die 104 are within the contemplated scope of the present disclosure.

In some embodiments, the one or more device regions 104a include at least one transistor. In some embodiments, the one or more device regions 104a include at least one NMOS transistor and/or at least one PMOS transistor. In some embodiments, the one or more device regions 104a includes various NMOS and/or PMOS devices, such as transistors, memories, or processors, and the like, interconnected to perform one or more functions. In some embodiments, the one or more device regions 104a include other devices, such as capacitors, resistors, diodes, photo-diodes, fuses, and the like in substrate 104b. In some embodiments, the functions of the devices include memory, processing, sensors, amplifiers, power distribution, input/output circuitry, or the like. The one or more device regions 104a are merely an example, and other devices may be included in the one or more device regions 104a. Other devices, configurations, arrangements and materials of the one or more device regions 104a are within the contemplated scope of the present disclosure.

Other configurations, arrangements and materials of semiconductor die 104 are within the contemplated scope of the present disclosure.

Integrated circuit 100A further includes at least one of conductor 110a, 110b, . . . 110f (collectively referred to as a “set of conductors 110”), at least one of conductor 112a, 112b, . . . , 112f (collectively referred to as a “set of conductors 112”) or at least one of conductor 114a, 114b, . . . , 114f (collectively referred to as a “set of conductors 114”). Other numbers of conductors in at least one of the set of conductors 110, 112 or 114 is within the scope of the present disclosure.

In some embodiments, at least one of the set of conductors 110, the set of conductors 112 and the set of conductors 114 is configured to electrically couple one of semiconductor die 102 or 104 to the other of semiconductor die 102 or 104. In some embodiments, at least one of the set of conductors 110, the set of conductors 112 and the set of conductors 114 is configured to electrically couple at least one of semiconductor die 102 or 104 to other portions of integrated circuit 100A.

The set of conductors 110 is on a surface of the semiconductor die 102 and a surface of the semiconductor die 104.

The set of conductors 114 is on a surface of the set of conductors 110. In some embodiments, each conductor 114a, 114b . . . 114f of the set of conductors 114 is directly on a corresponding surface of a corresponding conductor 110a, 110b, . . . 110f of the set of conductors 110.

The set of conductors 112 is on a surface of the set of conductors 114. In some embodiments, each conductor 112a, 112b, . . . 112f of the set of conductors 112 is directly on a corresponding surface of a corresponding conductor 114a, 114b, . . . 114f of the set of conductors 114.

In some embodiments, each conductor 114a, 114b, . . . 114f of the set of conductors 114 is between a corresponding conductor 110a, 110b, . . . 110f of the set of conductors 110 and a corresponding conductor 112a, 112b, . . . , 112f of the set of conductors 112.

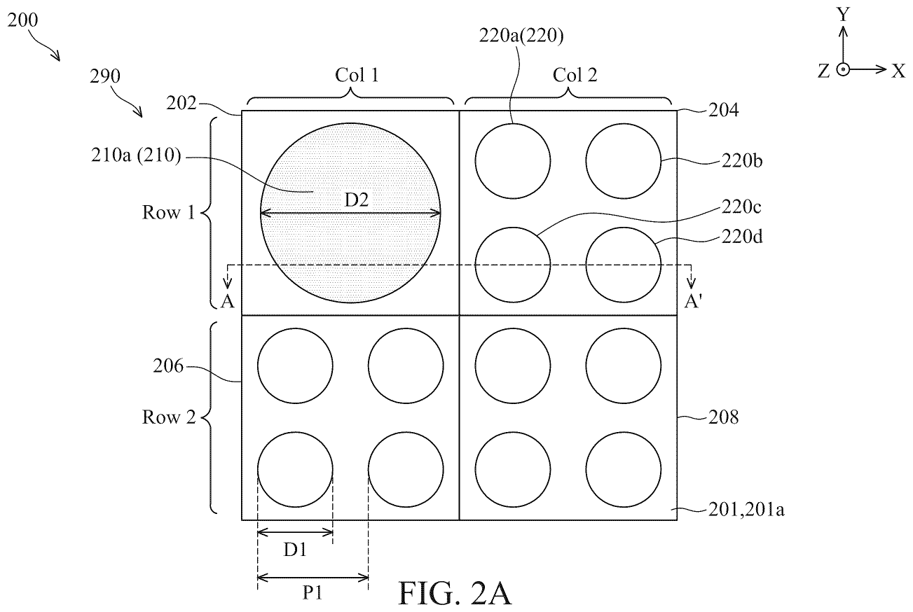

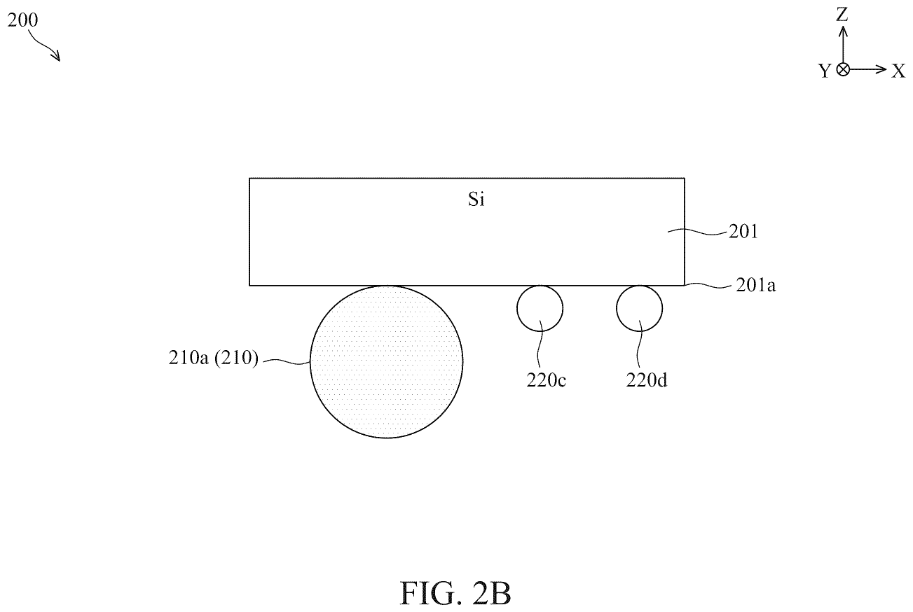

In some embodiments, at least one of the set of conductors 110 or the set of conductors 112 is a corresponding set of micro-bumps (FIGS. 2A-2B). In some embodiments, at least one conductor of the set of conductors 110 or 112 is a first micro-bump having a first diameter, and at least one conductor of the set of conductors 110 or 112 is a second micro-bump having a second diameter greater than the first diameter.

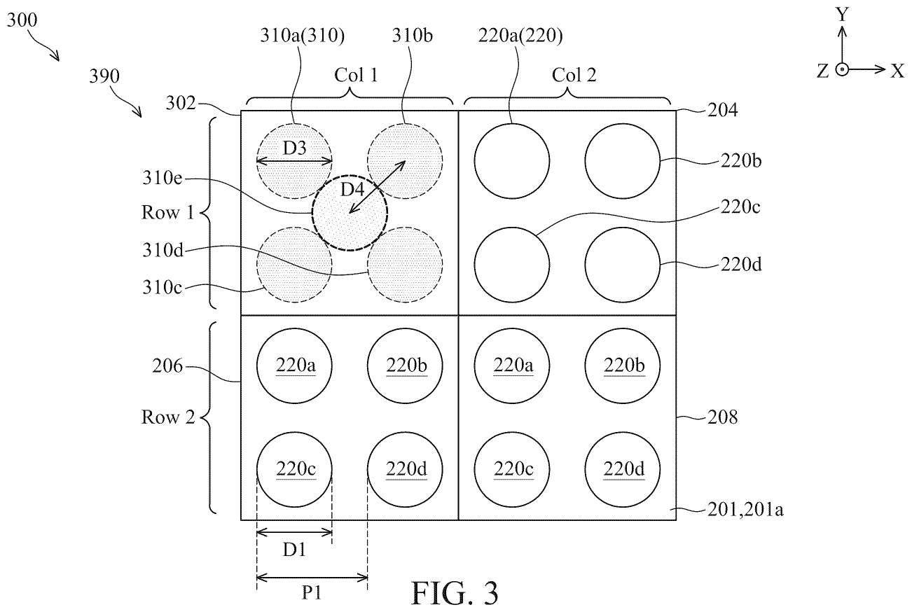

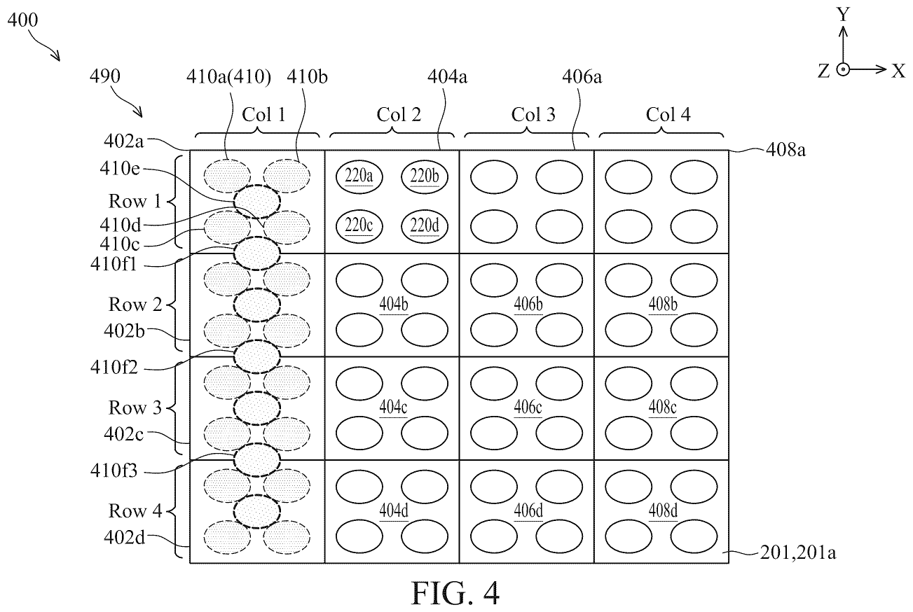

In some embodiments, at least one of the set of conductors 110 or the set of conductors 112 is a corresponding set of micro-bumps (FIGS. 3-4). In some embodiments, at least one conductor of the set of conductors 110 or 112 is the first micro-bump having the first diameter, and at least one conductor of the set of conductors 110 or 112 is the second micro-bump having the first diameter.

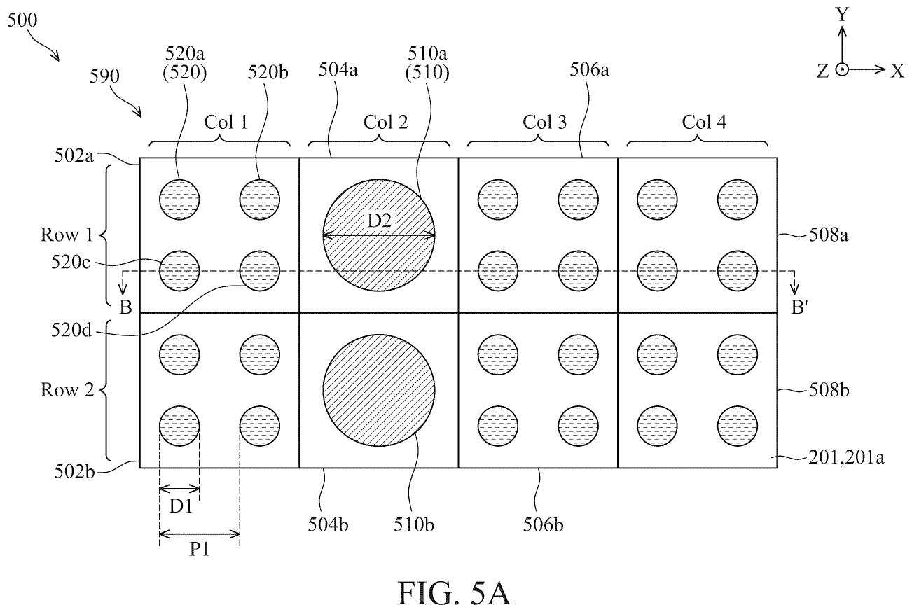

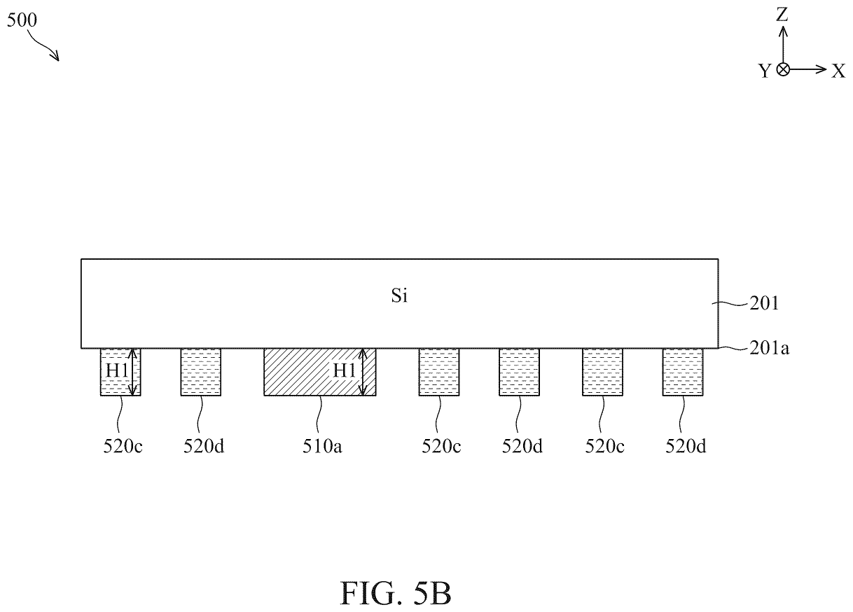

In some embodiments, at least one of the set of conductors 110 or the set of conductors 112 is a corresponding set of pillars (FIGS. 5A-5B). In some embodiments, at least one conductor of the set of conductors 110 or 112 is a first pillar having the first diameter, and at least one conductor of the set of conductors 110 or 112 is a second pillar having the second diameter.

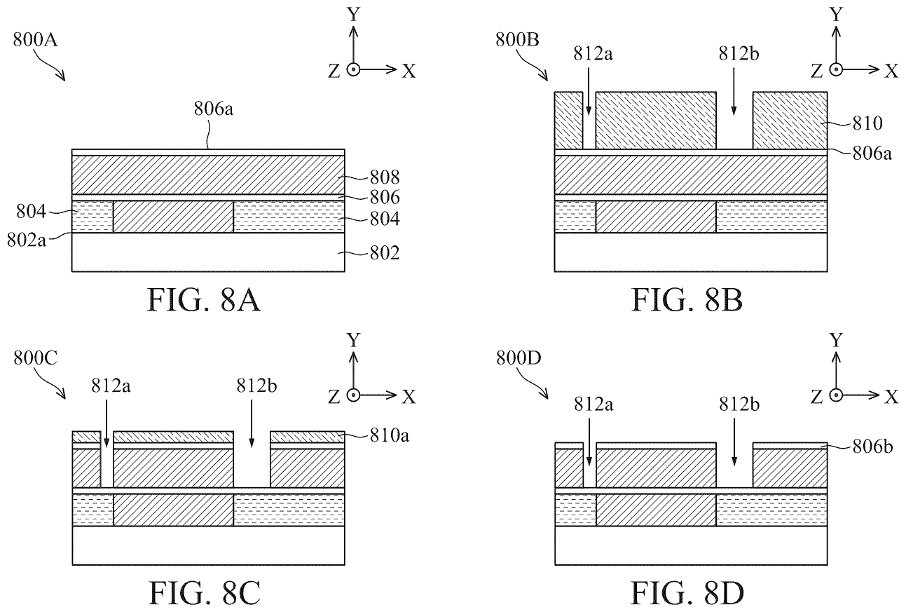

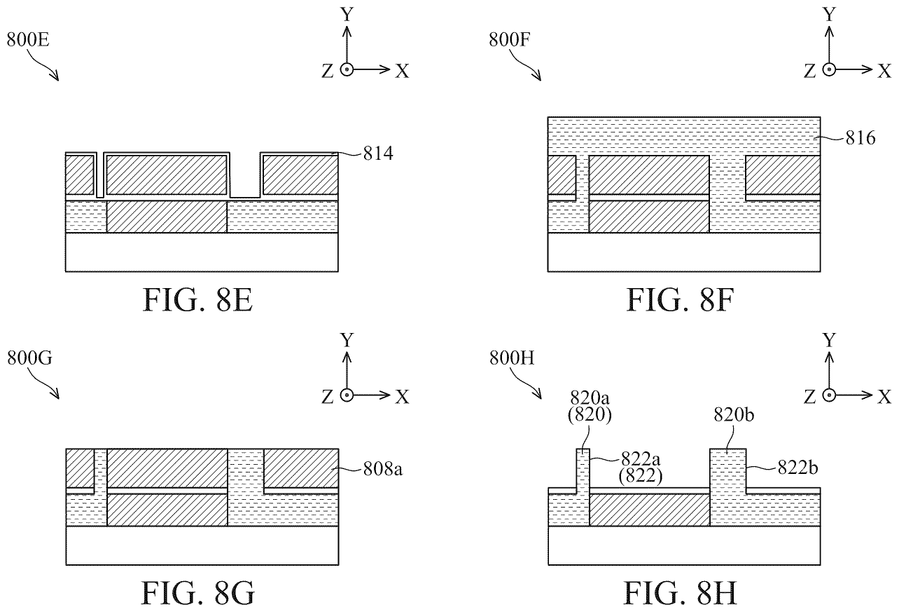

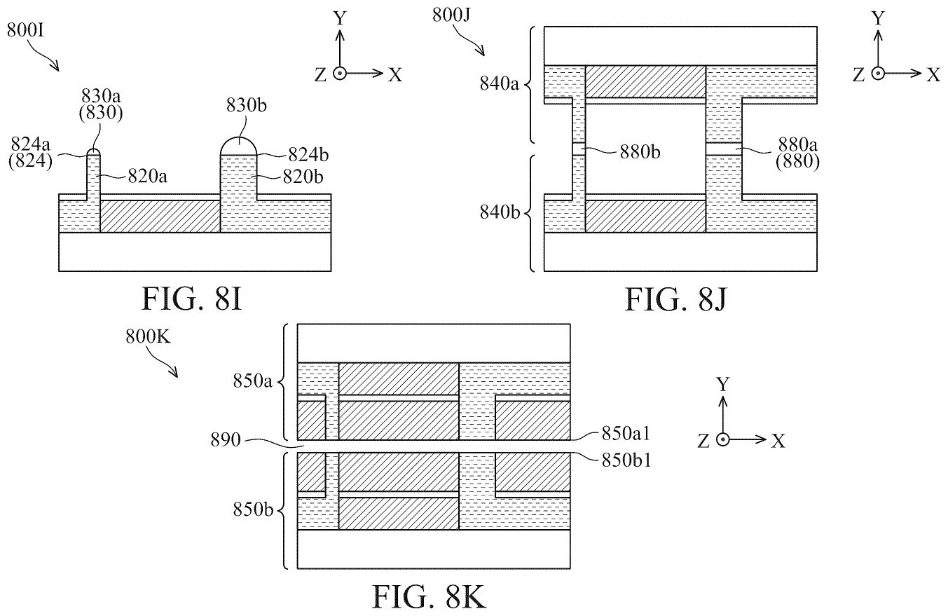

In some embodiments, the set of conductors 114 corresponds to a bonding layer 890 (FIG. 8K). In some embodiments, the set of conductors 114 corresponds to a set of bump joints 880 (FIG. 8J).

In some embodiments, the set of conductors 114 electrically couples the set of conductors 110 and the set of conductors 112 together.

In some embodiments, at least the set of conductors 110, 112 or 114 include conductive materials, such as copper, copper alloy, aluminum, alloys or combinations thereof. Conductive features (not shown) are also made of conductive materials. In some embodiments, other applicable materials are used. In some embodiments, at least the set of conductors 110, 112 or 114 include conductive materials which are heat resistant, such as tungsten (W), Cu, Al, or AlCu.

Other configurations, arrangements and materials of at least the set of conductors 110, 112 or 114 are within the contemplated scope of the present disclosure.

Integrated circuit 100A further includes an insulating material 108. The insulating material 108 encapsulates at least one of the set of conductors 110, the set of conductors 112 or the set of conductors 114.

In some embodiments, insulating material 108 includes a dielectric layer or a polymer layer. In some embodiments, insulating material 108 includes polyimide, polybenzoxazole (PBO), benzocyclobutene (BCB), an ajinomoto buildup film (ABF), a solder resist film (SR), or the like.

In some embodiments, insulating material 108 includes silicon oxide, silicon nitride, silicon carbide, silicon oxynitride, or the like. In some embodiments, insulating material 108 includes multiple dielectric layers of dielectric materials. One or more of the multiple dielectric layers are made of low dielectric constant (low-k) materials. In some embodiments, a top dielectric layer of the multiple dielectric layers (not shown) is made of SiO₂.

Other configurations, arrangements or materials of insulating material 108 are within the contemplated scope of the present disclosure.

Integrated circuit 100A further includes a molding material 106.

Molding material 106 is positioned between the semiconductor die 102 and semiconductor die 104. Molding material 106 fills some or all of the volume that is not occupied by semiconductor die 102 and the semiconductor die 104.

Molding material 106 encapsulates at least one of the set of conductors 110, the set of conductors 112, the set of conductors 114, the insulating material 108, the semiconductor die 102 or semiconductor die 104.

In some embodiments, molding material 106 is electrically insulating. In some embodiments, the molding material 106 is configured to provide package stiffness, provide a protective or hermetic cover, provide shielding, and/or provide a heat conductive path.

Molding material 106 includes a molding compound, a molding underfill, an epoxy, a resin, or another suitable material capable of filling some or all of the otherwise unoccupied volume between the semiconductor die 102 and semiconductor die 104.

Other configurations, arrangements or materials of molding material 106 are within the contemplated scope of the present disclosure.

In some embodiments, the set of conductors 110, the set of conductors 114, the set of conductors 114, the insulating region 108, the semiconductor die 102 and the semiconductor die 104 are part of a chip on wafer (COW) region 109 of integrated circuit 100A.

Integrated circuit 100A further includes an interconnect structure 119 on the COW region 109 of integrated circuit 100A. In some embodiments, interconnect structure 119 is on a surface of the set of conductors 112.

Interconnect structure 119 includes at least one conductor 120a, 120b, . . . , 120f (collectively referred to as a “set of conductors 120”), or at least one of conductor 122a, 122b, . . . 122f (collectively referred to as a “set of conductors 122”) embedded in an insulating material 124. Other numbers of conductors in at least one of the set of conductors 120 or 122 is within the scope of the present disclosure.

The set of conductors 122 extends in a first direction X. The set of conductors 120 extends in a second direction Y different from the first direction X.

In some embodiments, at least one conductor of the set of conductors 120 is also referred to as a via. In some embodiments, at least one conductor of the set of conductors 122 is also referred to as a redistribution layer (RDL), a conductive pad, post-passivation interconnect (PPI) structures, or package metallization (PM) stacks positioned within the one or more dielectric layers (not shown) of interconnect structure 119.

The set of conductors 120 and the set of conductors 122 are electrically coupled together. For example, conductor 120a is electrically coupled to conductor 122a. While the set of conductors 120 and the set of conductors 122 of FIG. 1A are described as one layer of interconnect structure 119, the set of conductors 120 and the set of conductors 122 are positioned on multiple layers of interconnect structure 119, in accordance with some embodiments.

In some embodiments, the set of conductors 120 and the set of conductors 122 are part of the same integral structure. In some embodiments, at least one conductor of the set of conductors 120 or 122 electrically couples one or more devices 136 (described below) to at least the one or more device regions 102a or 104a.

In some embodiments, interconnect structure 119 includes one or more contact plugs (not shown) and one or more conductive features (not shown).

Other configurations, arrangements and materials of interconnect structure 119 are within the contemplated scope of the present disclosure.

Integrated circuit 100A further includes a chip layer 131 on a surface of the interconnect structure 119.

The chip layer 131 includes a chip region 129, at least one of via 130a, 130b, . . . 130d (collectively referred to as a “set of vias 130”), and a molding material 134. Other numbers of vias in at least one of the set of vias 130 is within the scope of the present disclosure.

The chip region 129 includes at least one of via 132a or 132b (collectively referred to as a “set of vias 132”), one or more devices 136, at least one of conductor 140a, 140b, . . . , 140f (collectively referred to as a “set of conductors 140”), at least one of conductor 142a, 142b, 142f (collectively referred to as a “set of conductors 142”) or at least one of conductor 144a, 144b, . . . 144f (collectively referred to as a “set of conductors 144”).

Other numbers of vias in at least one of the set of vias 132 is within the scope of the present disclosure. Other numbers of conductors in at least one of the set of conductors 140, 142 or 144 is within the scope of the present disclosure.

The set of vias 132 is embedded in an insulating material 133. In some embodiments, the insulating material 133 is similar to the insulating material 108, and similar detailed description is therefore omitted.

In some embodiments, the set of vias 132 is referred to as a set of through Integrated Fan-Out (InFO) vias (TIVs). In some embodiments, the set of vias 132 extend through the insulating material 133 in the chip layer 131. In some embodiments, at least one TIV in the set of vias 132 extends partially into an interconnect structure 139. Other via types are within the contemplated scope of the present disclosure.

The set of vias 132 extend in the second direction Y. The set of vias 132 electrically couple the one or more devices 136 and the interconnect structure 139 together. In some embodiments, at least one via of the set of vias 132 includes one or more contact plugs (not shown).

In some embodiments, at least the set of vias 130 or 132 is made of conductive materials, such as copper, copper alloy, aluminum, alloys or combinations thereof. Conductive features (not shown) are also made of conductive materials. In some embodiments, other applicable materials are used. In some embodiments, at least the set of vias 130 or 132 include conductive materials which are heat resistant, such as tungsten (W), Cu, Al, or AlCu.

Other configurations, arrangements and materials of the set of vias 132 are within the contemplated scope of the present disclosure.

In some embodiments, the one or more devices 136 is a variation of one or more device regions 102a or 104a, and similar detailed description is therefore omitted.

In some embodiments, the one or more devices 136 is electrically coupled to at least one of the one or more device regions 102a or 104a by interconnect structure 119, the set of conductors 140, 142 and 144, and the set of conductors 110, 112 and 114.

In some embodiments, the one or more devices 136 is electrically coupled to other devices (not shown) by the set of vias 132, printed circuit board (PCB) 162, a set of electrical connectors 160, and the set of solder bumps 164.

The one or more devices 136 are different from the one or more device regions 104a or 102a. In some embodiments, the one or more devices 136 are the same as the one or more device regions 104a or 102a. Other devices, configurations, arrangements and materials of the one or more devices 136 are within the contemplated scope of the present disclosure.

In some embodiments, at least one of the set of conductors 140, the set of conductors 142 and the set of conductors 144 is a variation of one or more of at least one of the set of conductors 110, the set of conductors 112 and the set of conductors 114, and similar detailed description is therefore omitted.

In some embodiments, at least one of the set of conductors 140, the set of conductors 142 and the set of conductors 144 is configured to electrically couple one of semiconductor die 102 or 104 to the one or more devices 136.

The set of conductors 140 is on a surface of the interconnect structure 119.

The set of conductors 144 is on a surface of the set of conductors 140. In some embodiments, each conductor 144a, 144b, . . . , 144f of the set of conductors 144 is directly on a corresponding surface of a corresponding conductor 140a, 140b, . . . 140f of the set of conductors 140.

The set of conductors 142 is on a surface of the set of conductors 144. In some embodiments, each conductor 142a, 142b . . . 142f of the set of conductors 142 is directly on a corresponding surface of a corresponding conductor 144a, 144b, . . . 144f of the set of conductors 144.

In some embodiments, each conductor 144a, 144b, . . . 144f of the set of conductors 144 is between a corresponding conductor 140a, 140b, . . . 140f of the set of conductors 140 and a corresponding conductor 142a, 142b, . . . 142f of the set of conductors 142.

In some embodiments, at least one of the set of conductors 140 or the set of conductors 142 is a corresponding set of micro-bumps (FIGS. 2A-2B). In some embodiments, at least one conductor of the set of conductors 140 or 142 is a third micro-bump having a third diameter, and at least one conductor of the set of conductors 140 or 142 is a fourth micro-bump having a fourth diameter greater than the third diameter.

In some embodiments, at least one of the set of conductors 140 or the set of conductors 142 is a corresponding set of micro-bumps (FIGS. 3-4). In some embodiments, at least one conductor of the set of conductors 140 or 142 is the third micro-bump having the third diameter, and at least one conductor of the set of conductors 140 or 142 is the fourth micro-bump having the third diameter.

In some embodiments, at least one of the set of conductors 140 or the set of conductors 142 is a corresponding set of pillars (FIGS. 5A-5B). In some embodiments, at least one conductor of the set of conductors 140 or 142 is a third pillar having the third diameter, and at least one conductor of the set of conductors 140 or 142 is a fourth pillar having the fourth diameter.

In some embodiments, the set of conductors 144 corresponds to a bonding layer 890 (FIG. 8K). In some embodiments, the set of conductors 144 corresponds to a set of bump joints 880 (FIG. 8J).

In some embodiments, the set of conductors 144 electrically couples the set of conductors 140 and the set of conductors 142 together.

In some embodiments, at least the set of conductors 140, 142 or 144 include conductive materials, such as copper, copper alloy, aluminum, alloys or combinations thereof. Conductive features (not shown) are also made of conductive materials. In some embodiments, other applicable materials are used. In some embodiments, at least the set of conductors 140, 142 or 144 include conductive materials which are heat resistant, such as tungsten (W), Cu, Al, or AlCu.

Other configurations, arrangements and materials of at least the set of conductors 140, 142 or 144 are within the contemplated scope of the present disclosure.

The set of vias 130 is embedded in molding material 134. In some embodiments, the molding material 134 is similar to the molding material 106, and similar detailed description is therefore omitted.

In some embodiments, the set of vias 130 are referred to as a set of through-substrate vias (TSVs). In some embodiments, the set of vias 130 extend through the chip layer 131. In some embodiments, at least one TSV in the set of vias 130 extends partially into an interconnect structure 119 or 139. Other via types are within the contemplated scope of the present disclosure.

The set of vias 130 extend in the second direction Y. The set of vias 130 is between the interconnect structure 119 and the interconnect structure 139.

The set of vias 130 electrically couple the one or more device regions 102a or 104a to other structures or devices (not shown) by at least the interconnect structure 139 or 119. In some embodiments, at least one via of the set of vias 130 includes one or more contact plugs (not shown).

Other configurations, arrangements and materials of the set of vias 130 are within the contemplated scope of the present disclosure.

Molding material 134 is positioned between the interconnect structure 119 and interconnect structure 139. In some embodiments, molding material 134 fills some or all of the volume that is not occupied by the set of vias 130, the set of vias 132 and the one or more devices 136.

Molding material 134 encapsulates at least one of the set of vias 130, the set of vias 132 or the one or more devices 136.

In some embodiments, molding material 134 is electrically insulating. In some embodiments, the molding material 134 is configured to provide package stiffness, provide a protective or hermetic cover, provide shielding, and/or provide a heat conductive path.

Molding material 134 includes a molding compound, a molding underfill, an epoxy, a resin, or another suitable material capable of filling some or all of the otherwise unoccupied volume between the set of vias 130, the set of vias 132 and the one or more devices 136.

Other configurations, arrangements or materials of molding material 134 are within the contemplated scope of the present disclosure.

Integrated circuit 100A further includes an interconnect structure 139 on the chip layer 131 of integrated circuit 100A. In some embodiments, interconnect structure 139 is on a surface of the set of vias 130 or 132.

Interconnect structure 139 includes at least one conductor 150a, 150b, . . . 150f (collectively referred to as a “set of conductors 150”), or at least one of conductor 152a, 152b, . . . 152f (collectively referred to as a “set of conductors 152”) embedded in an insulating material 154. Other numbers of conductors in at least one of the set of conductors 150 or 152 is within the scope of the present disclosure.

The set of conductors 152 extends in a first direction X. The set of conductors 150 extends in a second direction Y different from the first direction X.

In some embodiments, at least one conductor of the set of conductors 150 is also referred to as a via. In some embodiments, at least one conductor of the set of conductors 152 is also referred to as an RDL, a conductive pad, PPI structures, or PM stacks positioned within the one or more dielectric layers (not shown) of interconnect structure 139.

The set of conductors 150 and the set of conductors 152 are electrically coupled together. For example, conductor 150a is electrically coupled to conductor 152a. While the set of conductors 150 and the set of conductors 152 of FIG. 1A are described as one layer of interconnect structure 139, the set of conductors 150 and the set of conductors 152 are positioned on multiple layers of interconnect structure 139, in accordance with some embodiments.

In some embodiments, the set of conductors 150 and the set of conductors 152 are part of the same integral structure. In some embodiments, at least one conductor of the set of conductors 150 or 152 electrically couples at least the one or more devices 136, the one or more device regions 102a, the one or more device regions 104a to other devices or components (not shown) by at least the set of solder bumps 164.

In some embodiments, interconnect structure 139 includes one or more contact plugs (not shown) and one or more conductive features (not shown).

In some embodiments, at least interconnect structure 119 or 139 is formed in a back-end-of-line (BEOL) process.

In some embodiments, at least the set of conductors 120, 122, 150 or 152 is made of conductive materials, such as copper, copper alloy, aluminum, alloys or combinations thereof. Conductive features (not shown) are also made of conductive materials. In some embodiments, other applicable materials are used. In some embodiments, at least the set of conductors 120, 122, 150 or 152, contact plug (not shown) and conductive features (not shown) include conductive materials which are heat resistant, such as tungsten (W), Cu, Al, or AlCu.

In some embodiments, at least the insulating material 134 or 154 is made of silicon oxide. In some embodiments, at least the insulating material 134 or 154 includes multiple dielectric layers of dielectric materials. One or more of the multiple dielectric layers are made of low dielectric constant (low-k) materials. In some embodiments, a top dielectric layer of the multiple dielectric layers (not shown) is made of SiO₂. Interconnect structure 119 or 139 is shown merely for illustrative purposes. Other configurations, arrangements and materials of interconnect structure 119 or 139 are within the contemplated scope of the present disclosure. In some embodiments, interconnect structure 119 or 139 includes one or more conductive lines and vias.

Integrated circuit 100A further includes at least one electrical connector 160a, 160b, . . . , 160f (collectively referred to as a “set of electrical connectors 160”). In some embodiments, the set of electrical connectors 160 corresponds to a set of Controlled Collapsible Chip Connection (C4) bumps. Other numbers of conductors in at least one of the set of electrical connectors 160 is within the scope of the present disclosure.

In some embodiments, the set of electrical connectors 160 are solder balls, conductive pillars, or other suitable conductive elements capable of providing electrical connections from PCB 162 to interconnect structure 139. In these embodiments, the set of electrical connectors 160 further include an under bump metallurgy (UBM) layer (not labelled) on a surface of the interconnect structure 139. In some embodiments, the UBM layer includes one or more conductive portions corresponding to the number of conductors in the set of electrical connectors 160 in the UBM layer. In some embodiments, UBM layer is formed on the surface of the interconnect structure 139. In some embodiments, UBM layer is formed on a metal pad (not shown). In some embodiments, UBM layer includes an adhesion layer and/or a wetting layer. In some embodiments. UBM layer includes at least a copper seed layer. In some embodiments, UBM layer includes titanium (Ti), titanium nitride (TiN), tantalum nitride (TaN), tantalum (Ta), or the like. Other configurations, arrangements and materials of UBM layer are within the contemplated scope of the present disclosure.

Other configurations, arrangements or materials of the set of electrical connectors 160 are within the contemplated scope of the present disclosure.

Integrated circuit 100A further includes a PCB 162. PCB 162 is configured to provide one or more electrical connections between interconnect structure 139 and a set of solder bumps 164 and/or one or more electrical structures external to an IC package comprising integrated circuit 100A.

Other configurations, arrangements or materials of PCB 162 are within the contemplated scope of the present disclosure.

Integrated circuit 100A further includes at least one of solder bump 164a, 164b, . . . , 164c (collectively referred to as a “set of solder bumps 164”). Other numbers of solder bumps in the set of solder bumps 164 is within the scope of the present disclosure.

In some embodiments, the set of solder bumps 164 is formed over a UBM layer (not shown). In some embodiments, one or more solder bumps 164a, 164b, . . . 164e of the set of solder bumps 164 includes a conductive material having a low resistivity, such as solder or a solder alloy. In some embodiments, a solder alloy includes Sn, Pb, Ag, Cu, Ni, Bi, or combinations thereof. Other configurations, arrangements and materials of the set of solder bumps 164 are within the contemplated scope of the present disclosure.

In some embodiments, integrated circuit 100A is electrically connected to one or more other package structures (not shown) by the set of solder bumps 164.

In some embodiments, integrated circuit 100A achieves one or more of the benefits discussed herein.

Other configurations, quantities of elements, arrangements or materials of integrated circuit 100A are within the contemplated scope of the present disclosure.

FIG. 1B is a cross-sectional view of an integrated circuit 100B, in accordance with some embodiments. In some embodiments, integrated circuit 100B is a vertical 3D die attachment, and is also referred to as “3D-IC.” Other packaging types for integrated circuit 100B are within the scope of the present disclosure.

Integrated circuit 100B is a variation of integrated circuit 100A (FIG. 1A), and similar detailed description is therefore omitted. For example, integrated circuit 100B corresponds to semiconductor die 102 and semiconductor die 104 being coupled by a set of conductors 110, 113 and 114 in a vertical manner (e.g., the second direction Y). Components that are the same or similar to those in FIGS. 1A-1B. 2A-2B, 3, 4, 5A-5B, 6, 7A-7B, and 8A-8K are given the same reference numbers, and similar detailed description is therefore omitted.

In comparison with integrated circuit 100A of FIG. 1A, the set of conductors 113 of integrated circuit 100B replaces the set of conductors 112, and similar detailed description is therefore omitted.

Integrated circuit 100B includes semiconductor die 102, semiconductor die 104, the set of conductors 110, the set of conductors 113, the set of conductors 114, molding material 106 and insulating material 108.

In comparison with the set of conductors 110 of FIG. 1A, the set of conductors 110 of integrated circuit 100B are positioned between semiconductor die 102 and the set of conductors 114, and similar detailed description is therefore omitted. In some embodiments, the set of conductors 110 of integrated circuit 100B are positioned on a surface of the semiconductor die 102 and on a surface of the set of conductors 114.

In comparison with the set of conductors 112 of FIG. 1A, the set of conductors 113 of integrated circuit 100B are positioned between semiconductor die 104 and the set of conductors 114, and similar detailed description is therefore omitted. In some embodiments, the set of conductors 113 are positioned on a surface of the semiconductor die 104 and on another surface of the set of conductors 114.

In some embodiments, the set of conductors 113 includes at least one of conductor 113a, 113b, . . . 113f. In some embodiments, at least one of conductor 113a, 113b, . . . 113f of the set of conductors 113 is similar to corresponding conductor 112a. 112b, . . . , 112f of the set of conductors 112, and similar detailed description is therefore omitted. Other numbers of conductors in at least one of the set of conductors 110, 113 or 114 is within the scope of the present disclosure.

Other configurations, arrangements and materials of at least the set of conductors 110, 113 or 114 are within the contemplated scope of the present disclosure.

Molding material 106 encapsulates at least one of semiconductor die 102 or semiconductor die 104.

Insulating material 108 is positioned between the semiconductor die 102 and semiconductor die 104. Insulating material 108 fills some or all of the volume that is not occupied by semiconductor die 102, semiconductor die 104, the set of conductors 110, the set of conductors 113, and the set of conductors 114. Insulating material 108 encapsulates at least one of the set of conductors 110, the set of conductors 113, the set of conductors 114.

In some embodiments, integrated circuit 100B achieves one or more of the benefits discussed herein.

Other configurations, quantities of elements, arrangements or materials of integrated circuit 100B are within the contemplated scope of the present disclosure.

FIGS. 2A-2B are diagrams of an integrated circuit 200, in accordance with some embodiments.

FIG. 2A is a top view of integrated circuit 200, in accordance with some embodiments.

FIG. 2B is a cross-sectional view of integrated circuit 200 as intersected by plane A-A′, in accordance with some embodiments.

Structural relationships including alignment, pitches, diameters, lengths and widths, as well as configurations and layers of at least one of integrated circuit 100A, 100B, 200, 300, 400, 500, 600, or 800A-800K are similar to the structural relationships and configurations and layers of another of 100A, 100B. 200, 300, 400, 500 or 800A-800K, and similar detailed description will not be described for brevity.

Integrated circuit 200 is an embodiment of integrated circuit 100A or 100B, and similar detailed description is therefore omitted.

Integrated circuit 200 includes a semiconductor die 201, and a set of conductors 210 and 220 arranged in an array of conductors 290. Stated differently, the set of conductors 210 and the set of conductors 220 are arranged in the array of conductors 290 on a surface 201a of the semiconductor die 201.

In some embodiments, semiconductor die 201 corresponds to at least one of semiconductor die 102, semiconductor die 104 or one or more devices 136 of FIGS. 1A-1B, and similar detailed description is therefore omitted.

The set of conductors 210 is an embodiment of at least one of the set of conductors 110, 112, 113, 140 or 142 of FIGS. 1A-1B, and similar detailed description is therefore omitted.

The set of conductors 220 is an embodiment of at least one of the set of conductors 110, 112, 113, 140 or 142 of FIGS. 1A-1B, and similar detailed description is therefore omitted.

The set of conductors 210 and the set of conductors 220 are arranged in the array of conductors 290.

The array of conductors 290 have regions (e.g., regions 202, 204, 206 and 208) or cells arranged in a set of rows and a set of columns. The array of conductors 290 have regions (e.g., regions 202, 204, 206 and 208) or cells arranged in 2 rows and 2 columns.

Other number of rows or columns are within the scope of the present disclosure. In some embodiments, the use of the term “region” is used interchangeably with “cell.”

In some embodiments, the array of conductors 290 has a rectangular shape. Other shapes of the array of conductors 290 are within the scope of the present disclosure. For example, in some embodiments, the array of conductors 290 has a honeycomb shape.

The rows in the array of conductors 290 are arranged in the first direction X. The columns in the array of conductors 290 are arranged in a second direction Y. In some embodiments, the second direction Y is perpendicular to the first direction X.

In some embodiments, the set of conductors 210 is usable as one or more conductors in the set of conductors 110, 112, 113, 140 or 142 of FIGS. 1A-1B. In some embodiments, the set of conductors 220 is usable as one or more conductors in the set of conductors 110, 112, 113, 140 or 142 of FIGS. 1A-1B.

The array of conductors 290 is divided into regions 202, 204, 206 and 208. A center of each region is separated from a center of an adjacent region by a distance (not labeled). In some embodiments, each region 202, 204, 206 and 208 occupies a same area as one another.

Region 202 includes the set of conductors 210. Region 202 is located in row 1 and column 1 of the array of conductors 290. In some embodiments, the set of conductors 210 is located at an intersection of a first row (e.g., row 1) of the set of rows and a first column (e.g., column 1) of the set of columns.

Other positions or numbers of regions for region 202 in the array of conductors 290 are within the scope of the present disclosure.

The set of conductors 210 includes at least conductor 210a. In some embodiments, conductor 210a of the set of conductors 210 is similar to one or more conductors of the set of conductors 110, 112, 113, 140 or 142, and similar detailed description is therefore omitted. Other numbers of conductors in at least one of the set of conductors 210 is within the scope of the present disclosure.

In some embodiments, the set of conductors 210 is a corresponding set of micro-bumps. In some embodiments, at least one conductor of the set of conductors 210 is a micro-bump having a diameter D2. In some embodiments, the diameter D2 is equal to a length (not labelled) in the first direction X of region 202. In some embodiments, the diameter D2 is equal to a height (not labelled) in the second direction Y of region 202.

In some embodiments, the set of conductors 210 is configured to supply a supply voltage VDD or a reference supply voltage VSS to semiconductor die 201. In some embodiments, the set of conductors 210 is configured to supply the supply voltage VDD or the reference supply voltage VSS to one or more devices in semiconductor die 201.

Other configurations and arrangements of region 202 are within the contemplated scope of the present disclosure.

Region 204 includes the set of conductors 220. Region 204 is located in row 1 and column 2 of the array of conductors 290. In some embodiments, the set of conductors 220 is located at an intersection of a first row (e.g., row 1) of the set of rows and a second column (e.g., column 2) of the set of columns. Other positions or numbers of regions for region 204 in the array of conductors 290 are within the scope of the present disclosure.

The set of conductors 220 includes at least conductor 220a, 220b, 220c or 220d. In some embodiments, at least one or more of conductor 220a, 220b, 220c or 220d of the set of conductors 220 is similar to one or more conductors of the set of conductors 110, 112, 113, 140 or 142, and similar detailed description is therefore omitted. Other numbers of conductors in at least one of the set of conductors 220 is within the scope of the present disclosure.

In some embodiments, the set of conductors 220 is a corresponding set of micro-bumps. In some embodiments, at least one conductor of the set of conductors 220 is a micro-bump having a diameter D1. The diameter D2 is greater than diameter D1. In some embodiments, the diameter D2 is at least 2 times greater than diameter D1. Stated differently, the diameter D2 is greater than or equal to a product of 2 and the diameter D1, in accordance with some embodiments.

In some embodiments, at least one conductor in the set of conductors 220 is separated from an adjacent conductor in the set of conductors 220 by a pitch P1. In some embodiments, adjacent elements are elements that are directly next to each other.

A relationship between the diameter D1, the diameter D2 and the pitch P1 is expressed by formula 1.

$$D 2 = ( D 1 + P 1 ) \qquad ( 1 )$$

In some embodiments, the diameter D2 is greater than formula 1 (e.g., a sum of the pitch P1 and diameter D1).

In some embodiments, if the diameter D2 is less than a value of formula 1, then a unit area of the set of conductors 210 is reduced thereby increasing the current density through the set of conductors 210 resulting in an electromigration (EM) violation from current density levels exceeding design thresholds, and increasing the power loss (from increased resistance (I²R losses)) from the set of conductors 210, and further resulting in more conductors in the set of conductors 210 in order to overcome the EM violation, thereby increasing the area occupied by the set of conductors 210 compared to other approaches.

In some embodiments, if the diameter D2 is equal to or greater than the value of formula 1, then the unit area of the set of conductors 210 is increased thereby decreasing the current density through the set of conductors 210, and not resulting in EM violations and decreasing power loss from the set of conductors 210, and further resulting in less conductors in the set of conductors 210 thereby decreasing the area occupied by the set of conductors 210 compared to other approaches.

In some embodiments, the set of conductors 220 is configured to transmit/receive a set of signals to/from semiconductor die 201. In some embodiments, the set of conductors 220 is configured to transmit/receive a set of signals to/from one or more devices in semiconductor die 201.

Other configurations and arrangements of region 204 are within the contemplated scope of the present disclosure.

Region 206 includes the set of conductors 220. Region 206 is located in row 2 and column 1 of the array of conductors 290. In some embodiments, the set of conductors 220 is located at an intersection of a second row (e.g., row 2) of the set of rows and the first column (e.g., column 1) of the set of columns. Other positions or numbers of regions for region 206 in the array of conductors 290 are within the scope of the present disclosure.

In some embodiments, region 206 includes a different number of conductors in the set of conductors 220 is within the scope of the present disclosure.

Other configurations and arrangements of region 206 are within the contemplated scope of the present disclosure.

Region 208 includes the set of conductors 220. Region 208 is located in row 2 and column 2 of the array of conductors 290. In some embodiments, the set of conductors 220 is located at an intersection of the second row (e.g., row 2) of the set of rows and the second column (e.g., column 2) of the set of columns. Other positions or numbers of regions for region 208 in the array of conductors 290 are within the scope of the present disclosure.

In some embodiments, region 208 includes a different number of conductors in the set of conductors 220 is within the scope of the present disclosure.

Other configurations and arrangements of region 208 are within the contemplated scope of the present disclosure.

Other configurations, arrangements and materials of at least the set of conductors 210 or 220 are within the contemplated scope of the present disclosure.

In some embodiments, by including the set of conductors 210 and 220 in integrated circuit 200, integrated circuit 200 includes an array of conductors/micro-bumps that have different diameters D1 and D2 thereby increasing the unit area of the set of conductors 210 with diameter D2 compared to the unit area of the set of conductors 220 with diameter D1.

In some embodiments, by increasing the unit area of the set of conductors 210 with diameter D2 thereby decreases the current density through the set of conductors 210 compared to other approaches, resulting in decreased power loss from the set of conductors 210.

In some embodiments, by increasing the unit area of the set of conductors 210 with diameter D2 thereby decreases the current density through the set of conductors 210 compared to other approaches, and therefore integrated circuit 200 does not have EM violations from current density levels exceeding design thresholds. In some embodiments, by integrated circuit 200 not having EM violations, integrated circuit 200 has less conductors in the set of conductors 210 compared to other approaches, and thereby decreases the area occupied by the set of conductors 210 compared to other approaches where additional conductors are used.

In some embodiments, integrated circuit 200 achieves one or more of the benefits discussed herein.

Other configurations, quantities of elements, arrangements, materials or quantities of elements of integrated circuit 200 are within the contemplated scope of the present disclosure.

FIG. 3 is a top view of integrated circuit 300, in accordance with some embodiments. Integrated circuit 300 is an embodiment of integrated circuit 100A or 100B, and similar detailed description is therefore omitted.

Integrated circuit 300 is a variation of integrated circuit 200 of FIGS. 2A-2B, and similar detailed description is therefore omitted. For example, in comparison with integrated circuit 200 of FIGS. 2A-2B, a set of conductors 310 of integrated circuit 300 replaces the set of conductors 210 of integrated circuit 200, and similar detailed description is therefore omitted.

Integrated circuit 300 includes semiconductor die 201, and a set of conductors 310 and 220 arranged in an array of conductors 390. Stated differently, the set of conductors 310 and the set of conductors 220 are arranged in the array of conductors 390 on the surface 201a of the semiconductor die 201.

The set of conductors 310 is an embodiment of at least one of the set of conductors 110, 112, 113, 140 or 142 of FIGS. 1A-1B, and similar detailed description is therefore omitted.

The set of conductors 310 and the set of conductors 220 are arranged in the array of conductors 390.

In some embodiments, the array of conductors 390 is a variation of the array of conductors 290 of FIGS. 2A-2B, and similar detailed description is therefore omitted. The array of conductors 390 has regions (e.g., regions 302, 204, 206 and 208) or cells arranged in a set of rows and a set of columns. The array of conductors 390 have regions (e.g., regions 302, 204, 206 and 208) or cells arranged in 2 rows and 2 columns. Other number of rows or columns are within the scope of the present disclosure.

In some embodiments, the array of conductors 390 has a rectangular shape. Other shapes of the array of conductors 390 are within the scope of the present disclosure. For example, in some embodiments, the array of conductors 390 has a honeycomb shape.

The rows in the array of conductors 390 are arranged in the first direction X. The columns in the array of conductors 390 are arranged in the second direction Y.

In some embodiments, the set of conductors 310 is usable as one or more conductors in the set of conductors 110, 112, 113, 140 or 142 of FIGS. 1A-1B.

The array of conductors 390 is divided into regions 302, 204, 206 and 208. A center of each region is separated from a center of an adjacent region by a distance (not labeled).

Region 302 includes the set of conductors 310. Region 302 is located in row 1 and column 1 of the array of conductors 390. In some embodiments, the set of conductors 310 is located at an intersection of a first row (e.g., row 1) of the set of rows and a first column (e.g., column 1) of the set of columns.

Other positions or numbers of regions for region 302 in the array of conductors 390 are within the scope of the present disclosure.

In some embodiments, the set of conductors 310 is a variation of the set of conductors 220 of FIGS. 2A-2B, and similar detailed description is therefore omitted.

The set of conductors 310 includes at least one of conductor 310a, 310b, 310c, 310d or 310c. In some embodiments, at least one of conductor 310a, 310b, 310c, 310d or 310e of the set of conductors 310 is similar to one or more conductors of the set of conductors 110, 112, 113, 140 or 142, and similar detailed description is therefore omitted. Other numbers of conductors in at least one of the set of conductors 310 is within the scope of the present disclosure.

In some embodiments, the set of conductors 310 is a corresponding set of micro-bumps. In some embodiments, at least one conductor of the set of conductors 310 is a micro-bump having a diameter D3. In some embodiments, the diameter D3 is equal to the diameter D1. In some embodiments, the diameter D3 is different from the diameter D1.

In some embodiments, at least one conductor in the set of conductors 310 is separated from an adjacent conductor in the set of conductors 310 by a distance D4.

In some embodiments, at least one conductor in the set of conductors 310 directly contacts at least one adjacent conductor in the set of conductors 310. In some embodiments, at least one of conductor 310a, 310b, 310c, 310d or 310e in the set of conductors 310 is integrally formed with another of at least one of conductor 310a, 310b, 310c, 310d or 310e in the set of conductors 310.

In some embodiments, at least one conductor in the set of conductors 310 is separated from at least one adjacent conductor in the set of conductors 310 by a distance (not labeled).

In some embodiments, conductor 310c is located at a center of region 302.

In some embodiments, a center of at least one of conductor 310a, 310b, 220a or 220b is aligned in the first direction with a center of another of conductor 310a, 310b, 220a or 220b. In some embodiments, a center of at least one of conductor 310c, 310d, 220c or 220d is aligned in the first direction with a center of another of conductor 310c, 310d, 220c or 220d.

In some embodiments, a center of at least one of conductor 310a, 310c. 220a or 220c is aligned in the first direction with a center of another of conductor 310a, 310c, 220a or 220c. In some embodiments, a center of at least one of conductor 310b, 310d, 220b or 220d is aligned in the first direction with a center of another of conductor 310b, 310d, 220b or 220d.

In some embodiments, the set of conductors 310 is configured to supply a supply voltage VDD or a reference supply voltage VSS to semiconductor die 201. In some embodiments, the set of conductors 310 is configured to supply the supply voltage VDD or the reference supply voltage VSS to one or more devices in semiconductor die 201.

Other configurations and arrangements of region 302 are within the contemplated scope of the present disclosure.

A number of conductors in the set of conductors 310 in region 302 is different from a number of conductors in the set of conductors 320 in at least one of region 204, 206 or 208. In some embodiments, the number of conductors in the set of conductors 310 in region 302 is greater than the number of conductors in the set of conductors 320 in at least one of region 204, 206 or 208.

In some embodiments, if the number of conductors in the set of conductors 310 in region 302 is not greater than the number of conductors in the set of conductors 220 in at least one of region 204, 206 or 208, then a unit area of the set of conductors 310 is reduced thereby increasing the current density through the set of conductors 310 resulting in an EM violation from current density levels exceeding design thresholds, and increasing the power loss (from increased resistance (I²R losses)) from the set of conductors 310, and further resulting in more regions in integrated circuit 300 that include the set of conductors 310 in order to overcome the EM violation, thereby increasing the area occupied by the set of conductors 310 compared to other approaches.

In some embodiments, if the number of conductors in the set of conductors 310 in region 302 is greater than the number of conductors in the set of conductors 220 in at least one of region 204, 206 or 208, then the unit area of the set of conductors 310 is increased thereby decreasing the current density through the set of conductors 310, and not resulting in EM violations and decreasing power loss from the set of conductors 310, and further resulting in less regions that are similar to region 302 and more regions similar to region 204, 206 or 208 thereby decreasing the area of regions that are similar to region 302 or increasing the area of regions similar to region 204, 206 or 208 compared to other approaches thus increasing the signal bump footprint and decreasing the power bump footprint.

Other configurations and arrangements of region 204, 206 or 208 are within the contemplated scope of the present disclosure.

Other configurations, arrangements and materials of at least the set of conductors 310 or 220 are within the contemplated scope of the present disclosure.

In some embodiments, by including the set of conductors 310 and 220 in integrated circuit 300, integrated circuit 300 includes an array of conductors/micro-bumps that have a different number of conductors/bumps thereby increasing the unit area of the set of conductors 310 compared to the unit area of the set of conductors 220.

In some embodiments, by increasing the unit area of the set of conductors 310 thereby decreases the current density through the set of conductors 310 compared to other approaches, resulting in decreased power loss from the set of conductors 310.

In some embodiments, by increasing the unit area of the set of conductors 310 thereby decreases the current density through the set of conductors 310 compared to other approaches, and therefore integrated circuit 300 does not have EM violations from current density levels exceeding design thresholds.

In some embodiments, by integrated circuit 300 not having EM violations, integrated circuit 300 has less regions that are similar to region 302 that are available for power bumps, and more regions similar to region 204, 206 or 208 that are available for signal bumps, thereby decreasing the area of regions that are similar to region 302 that are available for power bumps or increasing the area of regions similar to region 204, 206 or 208 that are available for signal bumps, thus increasing the signal bump footprint and decreasing the power bump footprint of integrated circuit 300 compared to other approaches.

In some embodiments, integrated circuit 300 achieves one or more of the benefits discussed herein.

Other configurations, quantities of elements, arrangements, materials or quantities of elements of integrated circuit 300 are within the contemplated scope of the present disclosure.

FIG. 4 is a top view of integrated circuit 400, in accordance with some embodiments. Integrated circuit 400 is an embodiment of integrated circuit 100A or 100B, and similar detailed description is therefore omitted.

Integrated circuit 400 is a variation of integrated circuit 300 of FIG. 3, and similar detailed description is therefore omitted. For example, in comparison with integrated circuit 300 of FIG. 3, an array of conductors 490 of integrated circuit 400 includes multiple rows of conductors having a diameter D3, and similar detailed description is therefore omitted.

In comparison with integrated circuit 300 of FIG. 3, a set of conductors 410 of integrated circuit 400 replaces the set of conductors 310 of integrated circuit 300, and similar detailed description is therefore omitted.

Integrated circuit 400 includes semiconductor die 201, and a set of conductors 410 and 220 arranged in an array of conductors 490. Stated differently, the set of conductors 410 and the set of conductors 220 are arranged in the array of conductors 490 on the surface 201a of the semiconductor die 201.

The set of conductors 410 is an embodiment of at least one of the set of conductors 110, 112, 113, 140 or 142 of FIGS. 1A-1B, and similar detailed description is therefore omitted.

The set of conductors 410 and the set of conductors 220 are arranged in the array of conductors 490.

In some embodiments, the array of conductors 490 is a variation of the array of conductors 390 of FIG. 3, and similar detailed description is therefore omitted. The array of conductors 490 has regions (e.g., regions 402a, 402b, 402c, 402d, 404a, 404b, 404c, 404d, 406a, 406b, 406c, 406d, 408a, 408b, 408c and 408d) or cells arranged in a set of rows and a set of columns. The array of conductors 490 have regions (e.g., regions 402a, 402b, 402c, 402d, 404a, 404b, 404c, 404d, 406a, 406b, 406c, 406d, 408a, 408b, 408c and 408d) or cells arranged in 4 rows and 4 columns. Other number of rows or columns are within the scope of the present disclosure.

In some embodiments, the array of conductors 490 has a rectangular shape. Other shapes of the array of conductors 490 are within the scope of the present disclosure. For example, in some embodiments, the array of conductors 490 has a honeycomb shape.

The rows in the array of conductors 490 are arranged in the first direction X. The columns in the array of conductors 490 are arranged in the second direction Y.

In some embodiments, the set of conductors 410 is usable as one or more conductors in the set of conductors 110, 112, 113, 140 or 142 of FIGS. 1A-1B.

The array of conductors 490 is divided into regions 402a, 402b, 402c, 402d, 404a, 404b, 404c, 404d, 406a, 406b, 406c, 406d, 408a, 408b, 408c and 408d. A center of each region is separated from a center of an adjacent region by a distance (not labeled).

In some embodiments, at least one of region 402a, 402b, 402c, 402d is similar to another of region 402a, 402b, 402c, 402d, and similar detailed description is therefore omitted. In some embodiments, at least one of region 404a, 404b, 404c, 404d is similar to another of region 404a, 404b, 404c, 404d, and similar detailed description is therefore omitted. In some embodiments, at least one of region 406a, 406b, 406c, 406d is similar to another of region 406a, 406b, 406c, 406d, and similar detailed description is therefore omitted. In some embodiments, at least one of region 408a, 408b, 408c, 408d is similar to another of region 408a, 408b, 408c, 408d, and similar detailed description is therefore omitted.

In some embodiments, at least one of region 402a, 402b, 402c, 402d is similar to region 302, and similar detailed description is therefore omitted.

In some embodiments, at least one of region 404a, 404b, 404c, 404d, 406a, 406b, 406c, 406d, 408a, 408b, 408c, 408d is similar to region 204, 206 or 208, and similar detailed description is therefore omitted.

At least one of region 402a, 402b, 402c or 402d includes the set of conductors 410. Region 402a is located in row 1 and column 1 of the array of conductors 490. Region 402b is located in row 2 and column 1 of the array of conductors 490. Region 402c is located in row 3 and column 1 of the array of conductors 490. Region 402d is located in row 4 and column 1 of the array of conductors 490. In some embodiments, the set of conductors 410 is located at one or more rows of the set of rows and a first column (e.g., column 1) of the set of columns.

While the array of conductors 490 shows that the set of conductors 410 are located in one column, in some embodiments, the set of conductors 410 are located in more than one column. In some embodiments, the set of conductors 410 are located in one or more columns that are positioned in a middle portion (e.g., column 2 or 3) of the array of conductors 490. In some embodiments, the set of conductors 410 are located in a column that is positioned in an end portion (e.g., column 1 or column 4) of the array of conductors 490.

Other positions or numbers of regions for region 402a, 402b, 402c or 402d in the array of conductors 490 are within the scope of the present disclosure.

At least one of region 404a, 404b, 404c, 404d includes the set of conductors 220. Region 404a is located in row 1 and column 2 of the array of conductors 490. Region 404b is located in row 2 and column 2 of the array of conductors 490. Region 404c is located in row 3 and column 2 of the array of conductors 490. Region 404d is located in row 4 and column 2 of the array of conductors 490.

At least one of region 406a, 406b, 406c, 406d includes the set of conductors 220. Region 406a is located in row 1 and column 3 of the array of conductors 490. Region 406b is located in row 2 and column 3 of the array of conductors 490. Region 406c is located in row 3 and column 3 of the array of conductors 490. Region 406d is located in row 4 and column 3 of the array of conductors 490.

At least one of region 408a, 408b, 408c, 408d includes the set of conductors 220. Region 408a is located in row 1 and column 4 of the array of conductors 490. Region 408b is located in row 2 and column 4 of the array of conductors 490. Region 408c is located in row 3 and column 4 of the array of conductors 490. Region 408d is located in row 4 and column 4 of the array of conductors 490.

Other positions or numbers of regions for region 404a, 404b, 404c, 404d, 406a, 406b, 406c, 406d, 408a, 408b, 408c or 408d in the array of conductors 490 are within the scope of the present disclosure.

In some embodiments, the set of conductors 410 is a variation of the set of conductors 310 of FIGS. 2A-2B, and similar detailed description is therefore omitted.

The set of conductors 410 includes at least one of conductor 410a, 410b, 410c, 410d, 410c, 410f1 or 410f2. In some embodiments, at least one of conductor 410a, 410b, 410c, 410d, 410e, 410f1 or 410f2 of the set of conductors 410 is similar to one or more conductors of the set of conductors 310, 210, 110, 112, 113, 140 or 142, and similar detailed description is therefore omitted. Other numbers of conductors in at least one of the set of conductors 410 is within the scope of the present disclosure.

In some embodiments, the set of conductors 410 for regions 402a, 402b or 402c includes either conductor 410f1 or 410f2. For example, conductor 410f1 is part of region 402a, and thus the set of conductors 410 in region 402a includes at least one of conductor 410a, 410b, 410c, 410d, 410c or 410f1. Similarly, conductor 410f2 is part of region 402b, and thus the set of conductors 410 in region 402b includes at least one of conductor 410a, 410b, 410c, 410d, 410e or 410f2. Similarly, conductor 410f1 is part of region 402c, and thus the set of conductors 410 in region 402c includes at least one of conductor 410a, 410b, 410c, 410d, 410e or 410f1.

In some embodiments, the set of conductors 410 for region 402d does not include either conductor 410f1 or 410f2, and thus the set of conductors 410 in region 402d includes at least one of conductor 410a, 410b, 410c, 410d or 410c.

In some embodiments, conductor 410f1 and 410f2 alternate with each other in the second direction Y.

In some embodiments, conductor 410f1 or 410f2 is located along a boundary between adjacent rows of the set of rows within the first column of the set of columns.

In some embodiments, conductor 410f1 is located along a boundary of region 402a and region 402b. In some embodiments, conductor 410f1 is located along a boundary of region 402c and region 402d.

In some embodiments, conductor 410f1 is located along a boundary of region 402b and region 402c.

In some embodiments, the set of conductors 410 is a corresponding set of micro-bumps. In some embodiments, at least one conductor of the set of conductors 410 is a micro-bump having the diameter D3.

In some embodiments, at least one conductor in the set of conductors 410 is separated from an adjacent conductor in the set of conductors 410 by the distance D4.

In some embodiments, at least one conductor in the set of conductors 410 directly contacts at least one adjacent conductor in the set of conductors 410. In some embodiments, at least one of conductor 410a, 410b, 410c, 410d, 410c, 410f1 or 410f2 in the set of conductors 410 is integrally formed with another of at least one of conductor 410a, 410b, 410c, 410d, 410e, 410f1 or 410f2 in the set of conductors 410.

In some embodiments, at least one conductor in the set of conductors 410 is separated from at least one adjacent conductor in the set of conductors 410 by a distance (not labeled).

In some embodiments, conductor 410e is located at a center of region 402.

In some embodiments, a center of at least one of conductor 410e, 410f1 or 410f2 is aligned in the second direction Y with a center of another of conductor 410c, 410f1 or 410f2.

In some embodiments, a center of at least one of conductor 410a, 410b, 220a or 220b is aligned in the first direction X with a center of another of conductor 410a, 410b, 220a or 220b. In some embodiments, a center of at least one of conductor 410c, 410d, 220c or 220d is aligned in the first direction X with a center of another of conductor 410c, 410d, 220c or 220d.

In some embodiments, a center of at least one of conductor 410a, 410c, 220a or 220c is aligned in the second direction Y with a center of another of conductor 410a, 410c, 220a or 220c. In some embodiments, a center of at least one of conductor 410b, 410d, 220b or 220d is aligned in the second direction Y with a center of another of conductor 410b, 410d, 220b or 220d.

In some embodiments, the set of conductors 410 is configured to supply a supply voltage VDD or a reference supply voltage VSS to semiconductor die 201. In some embodiments, the set of conductors 410 is configured to supply the supply voltage VDD or the reference supply voltage VSS to one or more devices in semiconductor die 201.

Other configurations and arrangements of region 402a, 402b, 402c or 402d are within the contemplated scope of the present disclosure.

A number of conductors in the set of conductors 410 in at least one of region 402a, 402b, 402c or 402d is different from a number of conductors in the set of conductors 220 in at least one of region 404a, 404b, 404c, 404d, 406a, 406b, 406c, 406d, 408a, 408b, 408c or 408d. In some embodiments, the number of conductors in the set of conductors 410 in at least one of region 402a, 402b, 402c or 402d is greater than the number of conductors in the set of conductors 220 in at least one of region 404a, 404b, 404c, 404d, 406a, 406b, 406c, 406d, 408a, 408b, 408c or 408d.

In some embodiments, if the number of conductors in the set of conductors 410 in region 402 is not greater than the number of conductors in the set of conductors 220 in at least one of region 404a, 404b, 404c, 404d, 406a, 406b, 406c, 406d, 408a, 408b, 408c or 408d, then a unit area of the set of conductors 410 is reduced thereby increasing the current density through the set of conductors 410 resulting in an EM violation from current density levels exceeding design thresholds, and increasing the power loss (from increased resistance (I²R losses)) from the set of conductors 410, and further resulting in more regions in integrated circuit 400 that include the set of conductors 410 in order to overcome the EM violation, thereby increasing the area occupied by the set of conductors 410 compared to other approaches.

In some embodiments, if the number of conductors in the set of conductors 410 in region 402 is greater than the number of conductors in the set of conductors 320 in at least one of region 404, 406 or 408, then the unit area of the set of conductors 410 is increased thereby decreasing the current density through the set of conductors 410, and not resulting in EM violations and decreasing power loss from the set of conductors 410, and further resulting in less regions that are similar to region 402 and more regions similar to region 404, 406 or 408 thereby decreasing the area of regions that are similar to region 402 or increasing the area of regions similar to region 404, 406 or 408 compared to other approaches thus increasing the signal bump footprint and decreasing the power bump footprint.

Other configurations and arrangements of region 404, 406 or 408 are within the contemplated scope of the present disclosure.

Other configurations, arrangements and materials of at least the set of conductors 410 or 220 are within the contemplated scope of the present disclosure.

In some embodiments, integrated circuit 400 achieves one or more of the benefits discussed herein.

Other configurations, quantities of elements, arrangements, materials or quantities of elements of integrated circuit 400 are within the contemplated scope of the present disclosure.

FIGS. 5A-5B are diagrams of an integrated circuit 500, in accordance with some embodiments.

FIG. 5A is a top view of integrated circuit 500, in accordance with some embodiments.

FIG. 5B is a cross-sectional view of integrated circuit 500 as intersected by plane B-B′, in accordance with some embodiments. Integrated circuit 500 is an embodiment of integrated circuit 100A or 100B, and similar detailed description is therefore omitted.

Integrated circuit 500 is a variation of integrated circuit 300 of FIGS. 2A-2B, and similar detailed description is therefore omitted. For example, in comparison with integrated circuit 200 of FIGS. 2A-2B, an array of conductors 590 of integrated circuit 500 corresponds to a set of conductive pillars, and similar detailed description is therefore omitted.

In comparison with integrated circuit 200 of FIGS. 2A-2B, a set of conductors 510 of integrated circuit 500 replaces the set of conductors 210 of integrated circuit 200, and a set of conductors 520 of integrated circuit 500 replaces the set of conductors 220 of integrated circuit 200, and similar detailed description is therefore omitted.

Integrated circuit 500 includes semiconductor die 201, and a set of conductors 510 and 520 arranged in an array of conductors 590. Stated differently, the set of conductors 510 and the set of conductors 520 are arranged in the array of conductors 590 on the surface 201a of the semiconductor die 201.

The set of conductors 510 is an embodiment of at least one of the set of conductors 110, 112, 113, 140 or 142 of FIGS. 1A-1B, and similar detailed description is therefore omitted.

The set of conductors 510 and the set of conductors 520 are arranged in the array of conductors 590.

In some embodiments, the array of conductors 590 is a variation of the array of conductors 390 of FIG. 3, and similar detailed description is therefore omitted. The array of conductors 590 has regions (e.g., regions 502a, 502b, 504a, 504b, 506a, 506b, 508a and 508b) or cells arranged in a set of rows and a set of columns. The array of conductors 590 have regions (e.g., regions 502a, 502b, 504a, 504b, 506a, 506b, 508a and 508b) or cells arranged in 2 rows and 4 columns. Other number of rows or columns are within the scope of the present disclosure.

In some embodiments, the array of conductors 590 has a rectangular shape. Other shapes of the array of conductors 590 are within the scope of the present disclosure. For example, in some embodiments, the array of conductors 590 has a honeycomb shape.

The rows in the array of conductors 590 are arranged in the first direction X. The columns in the array of conductors 590 are arranged in the second direction Y.

In some embodiments, the set of conductors 510 is usable as one or more conductors in the set of conductors 110, 112, 113, 140 or 142 of FIGS. 1A-1B.

The array of conductors 590 is divided into regions 502a, 502b, 504a, 504b, 506a, 506b, 508a and 508b. A center of each region is separated from a center of an adjacent region by a distance (not labeled).

In some embodiments, at least one of region 502a, 502b is similar to another of region 502a, 502b, and similar detailed description is therefore omitted. In some embodiments, at least one of region 504a, 504b is similar to another of region 504a, 504b, and similar detailed description is therefore omitted. In some embodiments, at least one of region 506a, 506b is similar to another of region 506a, 506b, and similar detailed description is therefore omitted. In some embodiments, at least one of region 508a, 508b is similar to another of region 508a, 508b, and similar detailed description is therefore omitted.

In some embodiments, at least one of region 502a, 502b is similar to region 202, and similar detailed description is therefore omitted.

In some embodiments, at least one of region 504a, 504b, 506a, 506b, 508a, 508b is similar to region 204, 206 or 208, and similar detailed description is therefore omitted.

At least one of region 502a or 502b includes the set of conductors 520. Region 502a is located in row 1 and column 1 of the array of conductors 590. Region 502b is located in row 2 and column 1 of the array of conductors 590. In some embodiments, the set of conductors 520 is located at one or more rows of the set of rows and a first column (e.g., column 1) of the set of columns.

Other positions or numbers of regions for region 502a or 502b in the array of conductors 590 are within the scope of the present disclosure.

At least one of region 504a, 504b includes the set of conductors 510. Region 504a is located in row 1 and column 2 of the array of conductors 590. Region 504b is located in row 2 and column 2 of the array of conductors 590.

While the array of conductors 590 shows that the set of conductors 510 are located in one column, in some embodiments, the set of conductors 510 are located in more than one column. In some embodiments, the set of conductors 510 are located in one or more columns that are positioned in a middle portion (e.g., column 2 or 3) of the array of conductors 590. In some embodiments, the set of conductors 510 are located in one or more columns that are positioned in an end portion (e.g., column 1 or column 4) of the array of conductors 590.

Other positions or numbers of regions for region 504a or 504b in the array of conductors 590 are within the scope of the present disclosure.

At least one of region 506a, 506b includes the set of conductors 520. Region 506a is located in row 1 and column 3 of the array of conductors 590. Region 506b is located in row 2 and column 3 of the array of conductors 590.

At least one of region 508a, 508b includes the set of conductors 520. Region 508a is located in row 1 and column 4 of the array of conductors 590. Region 508b is located in row 2 and column 4 of the array of conductors 590.

Other positions or numbers of regions for region 506a, 506b, 508a or 508b in the array of conductors 590 are within the scope of the present disclosure.

In some embodiments, the set of conductors 510 is a variation of the set of conductors 210 of FIGS. 2A-2B, and similar detailed description is therefore omitted.

The set of conductors 510 includes at least one of conductor 510a or 510b. In some embodiments, at least one of conductor 510a or 510b of the set of conductors 510 is similar to one or more conductors of the set of conductors 210, 110, 112, 113, 140 or 142, and similar detailed description is therefore omitted. Other numbers of conductors in at least one of the set of conductors 510 is within the scope of the present disclosure.

In some embodiments, at least one of the set of conductors 510 is a corresponding set of conductive pillars. In some embodiments, at least one conductor of the set of conductors 510 is a conductive pillar having the diameter D2.

In some embodiments, the diameter D2 is equal to a length (not labelled) in the first direction X of region 202. In some embodiments, the diameter D2 is equal to a height (not labelled) in the second direction Y of region 202.

In some embodiments, conductor 510a in region 504a is separated from conductor 510a in region 504b by a distance (not labelled).

In some embodiments, conductor 510a in region 504a directly contacts conductor 510a in region 504b. In some embodiments, conductor 510a in region 504a is integrally formed with conductor 510a in region 504b.

In some embodiments, conductor 510a is located at a center of at least one of region 504a or 504b.

In some embodiments, a center of conductor 510a in region 504a is aligned in the second direction Y with a center of conductor 510a in region 504b.

In some embodiments, the set of conductors 510 is configured to supply a supply voltage VDD or a reference supply voltage VSS to semiconductor die 201. In some embodiments, the set of conductors 510 is configured to supply the supply voltage VDD or the reference supply voltage VSS to one or more devices in semiconductor die 201.

Other configurations and arrangements of region 502a or 502b are within the contemplated scope of the present disclosure.

In some embodiments, the set of conductors 520 is a variation of the set of conductors 220 of FIGS. 2A-2B, and similar detailed description is therefore omitted.

The set of conductors 520 includes at least conductor 520a, 520b, 520c or 520d. In some embodiments, at least one or more of conductor 520a, 520b, 520c or 520d of the set of conductors 520 is similar to one or more conductors of the set of conductors 220, 110, 112, 113, 140 or 142, and similar detailed description is therefore omitted. Other numbers of conductors in at least one of the set of conductors 520 is within the scope of the present disclosure.

In some embodiments, a center of at least one of conductor 520a or 520c is aligned in the second direction Y with a center of another of conductor 520a or 520c. In some embodiments, a center of at least one of conductor 520b or 520d is aligned in the second direction Y with a center of another of conductor 520b or 520d.

In some embodiments, the set of conductors 520 is a corresponding set of conductive pillars. In some embodiments, at least one conductor of the set of conductors 520 is a conductive pillar having the diameter D1. The diameter D2 is greater than diameter D1. In some embodiments, the diameter D2 is at least 2 times greater than diameter D1. Stated differently, the diameter D2 is greater than or equal to a product of 2 and the diameter D1, in accordance with some embodiments.

In some embodiments, at least one conductor in the set of conductors 520 or at least one conductor in the set of conductors 510 has a height H1 in the second direction Y.

In some embodiments, at least one conductor in the set of conductors 520 is separated from an adjacent conductor in the set of conductors 520 by the pitch P1.

A relationship between the diameter D1, the diameter D2 and the pitch P1 is expressed by formula 1 (as described above). In some embodiments, the diameter D2 is greater than formula 1 (e.g., a sum of the pitch P1 and diameter D1).

In some embodiments, if the diameter D2 is less than a value of formula 1, then a unit area of the set of conductors 510 is reduced thereby increasing the current density through the set of conductors 510 resulting in an electromigration (EM) violation from current density levels exceeding design thresholds, and increasing the power loss (from increased resistance (I²R losses)) from the set of conductors 510, and further resulting in more conductors in the set of conductors 510 in order to overcome the EM violation, thereby increasing the area occupied by the set of conductors 510 compared to other approaches.

In some embodiments, if the diameter D2 is equal to or greater than the value of formula 1, then the unit area of the set of conductors 510 is increased thereby decreasing the current density through the set of conductors 510, and not resulting in EM violations and decreasing power loss from the set of conductors 510, and further resulting in less conductors in the set of conductors 510 thereby decreasing the area occupied by the set of conductors 510 compared to other approaches.

In some embodiments, the set of conductors 520 is configured to transmit/receive a set of signals to/from semiconductor die 201. In some embodiments, the set of conductors 520 is configured to transmit/receive a set of signals to/from one or more devices in semiconductor die 201.

Other configurations and arrangements of region 502a, 502b, 506a, 506b, 508a and 508b are within the contemplated scope of the present disclosure.

Other configurations, arrangements and materials of at least the set of conductors 510 or 520 are within the contemplated scope of the present disclosure.

In some embodiments, integrated circuit 500 achieves one or more of the benefits discussed herein.

Other configurations, quantities of elements, arrangements, materials or quantities of elements of integrated circuit 500 are within the contemplated scope of the present disclosure.

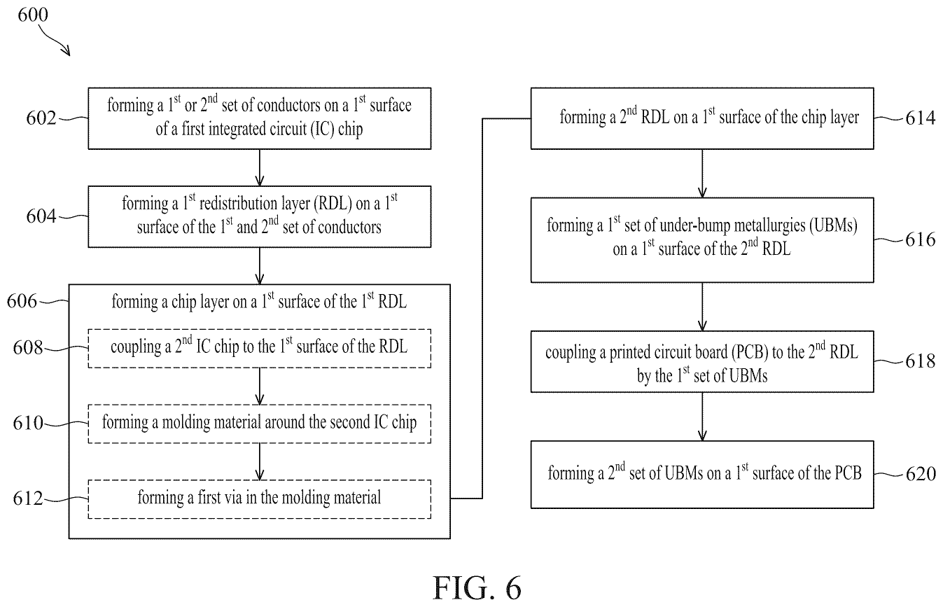

FIG. 6 is a functional flow chart of a method 600 of manufacturing an IC device, in accordance with some embodiments. It is understood that additional operations may be performed before, during, and/or after at least one of method 600 depicted in FIG. 6, and that some other processes may only be briefly described herein.

In some embodiments, other order of operations of at least one of method 600 or method 700 is within the scope of the present disclosure. At least one of method 600 or 700 include exemplary operations, but the operations are not necessarily performed in the order shown. Operations may be combined, divided, added, replaced, changed order, and/or eliminated as appropriate, in accordance with the spirit and scope of disclosed embodiments. In some embodiments, one or more of the operations of at least method 600 or 700 is not performed.

In some embodiments, the method 600 is usable to manufacture or fabricate at least one of integrated circuit 100A, 100B, 200, 300, 400, 500 or 800A-800K.

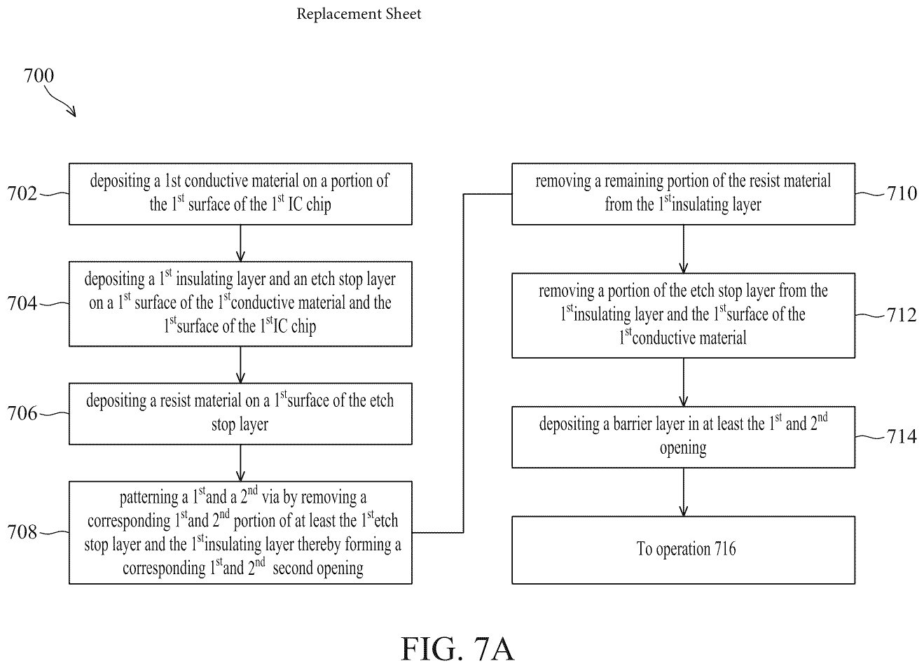

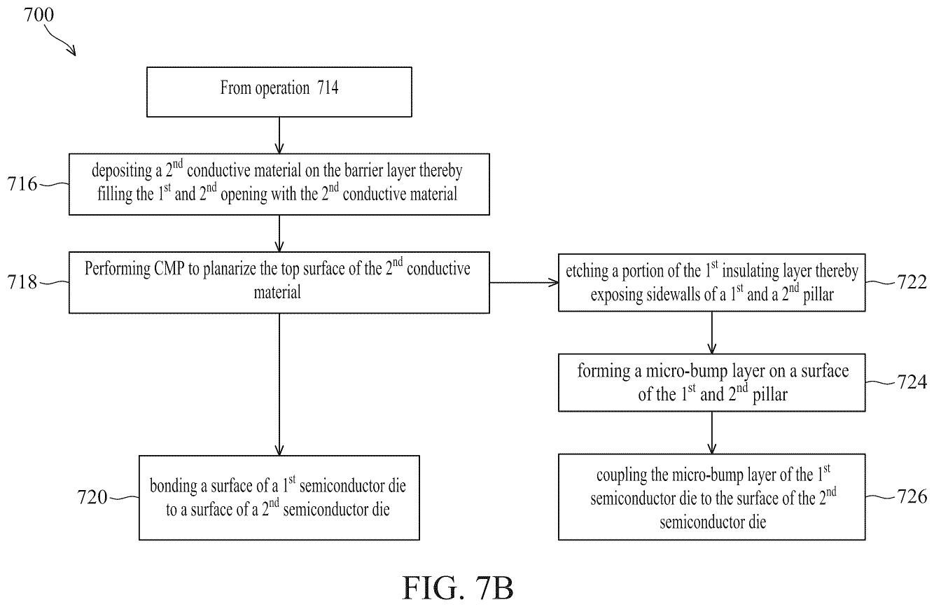

In operation 602 of method 600, at least one of a first set of conductors or a second set of conductors are formed on a first surface of a first integrated circuit (IC) chip. In some embodiments, method 700 in FIGS. 7A-7B is an embodiment of at least operation 602, and similar detailed description is therefore omitted.

In some embodiments, the first set of conductors includes at least one of the set of conductors 110, 112, 114, 210, 310, 410, 510 or 830.

In some embodiments, the second set of conductors includes another of at least one of the set of conductors 113, 114, 220, 520 or 830.

In some embodiments, the first surface includes surface 201a or 824.

In some embodiments, the first IC chip includes at least one of semiconductor die 102, 104, 201 or 802.

In operation 604 of method 600, a first redistribution layer (RDL) is formed on a first surface of the first set of conductors and the second set of conductors. In some embodiments, the first RDL is coupled to the first set of conductors and the second set of conductors.

In some embodiments, the first RDL includes interconnect structure 119. In some embodiments, the first surface of the first set of conductors and the second set of conductors includes at least surface 119a.

In some embodiments, operation 604 includes depositing an insulating material (e.g., similar to insulating material 124) over the COW region 109, performing one or more etching processes to form one or more openings in the insulating material 124, filling the one or more openings with one or more conductive materials, and removing the one or more conductive materials that protrude from the one or more openings.

In operation 606 of method 600, a chip layer 131 is formed on a first surface of the first RDL. In some embodiments, the first surface of the first RDL includes surface 119b.

In some embodiments, operation 606 includes at least one of operation 608, 610 or 612.

In operation 608 of method 600, a second IC chip is coupled to the first surface of the RDL.

In some embodiments, the second IC chip is electrically coupled to the first IC chip. In some embodiments, the second IC chip is coupled to the first surface of the RDL by the set of conductors 140, 142 and 144. In some embodiments, the second IC chip is coupled to the first surface of the RDL by the set of conductors 140, 142 and 144 by a process similar to method 700, and similar detailed description is therefore omitted.

In some embodiments, the second IC chip includes the one or more devices 136.

In some embodiments, the second IC chip includes chip region 129.

In operation 610 of method 600, a molding material is formed around the second IC chip thereby/encapsulating the second IC chip.

In operation 612 of method 600, a first through-via is formed in the molding material.

In some embodiments, the first through-via includes the set of vias 130 or 132. In some embodiments, the molding material includes molding material 134. In some embodiments, the molding material includes insulating material 133.

In some embodiments, operation 612 includes forming a first set of self-aligned contacts (SACs) in the molding material or insulating region.

In some embodiments, operation 612 includes forming a TSV opening (or a TIV opening) to extend through the molding material by one or more etching processes. In some embodiments, the TIV process is similar to the TSV process, and similar detailed description is therefore omitted. In some embodiments, after the TSV opening is formed, a liner is formed on sidewalls of the TSV opening to act as an isolation layer, such that conductive materials of TSV and the chip layer 131 do not directly contact with each other. In some embodiments, afterwards, a diffusion barrier layer is conformally formed on the liner and on the bottom of the TSV opening. In some embodiments, the diffusion barrier layer is used to prevent conductive material, which will be formed later, from migrating to the one or more device regions 136. In some embodiments, after the diffusion barrier layer is formed, conductive material is used to fill into the TSV opening. In some embodiments, afterwards, excess liner, diffusion barrier layer, and conductive material, which are on the outside of the TSV opening, are removed by a planarization process, such as a chemical mechanical polishing (CMP) process, although any suitable removal process may be used.

In some embodiments, the liner is made of an insulating material, such as oxides or nitrides. In some embodiments, the liner is formed by using a plasma enhanced chemical vapor deposition (PECVD) process or other applicable processes. In some embodiments, the liner is a single layer or multi-layers.

In some embodiments, the diffusion barrier layer is made of Ta, TaN, Ti, TiN or CoW. In some embodiments, the diffusion barrier layer is formed by a physically vapor deposition (PVD) process. In some embodiments, the diffusion barrier layer is formed by plating. In some embodiments, the conductive material is made of copper, copper alloy, aluminum, aluminum alloys, or combinations thereof. Alternatively, other applicable materials may be used.

In operation 614 of method 600, a second RDL is formed on a first surface of the chip layer. In some embodiments, the chip layer is positioned between the first redistribution layer and the second RDL.

In some embodiments, the second RDL includes interconnect structure 139. In some embodiments, the first surface of the chip layer includes at least surface 139a.

In some embodiments, operation 614 includes depositing an insulating material (e.g., similar to insulating material 154) over the chip layer 131, performing one or more etching processes to form one or more openings in the insulating material 154, filling the one or more openings with one or more conductive materials, and removing the one or more conductive materials that protrude from the one or more openings.

In operation 616 of method 600, a first set of UBMs is formed on a first surface of the second RDL.

In some embodiments, the first set of UBMs includes the set of electrical connectors 160. In some embodiments, the first surface of the second RDL includes at least surface 139b.

In some embodiments, the first set of UBMs includes at least an adhesion layer or a wetting layer. In some embodiments, the first set of UBMs includes titanium (Ti), titanium nitride (TiN), tantalum nitride (TaN), tantalum (Ta), or the like. In some embodiments, the first set of UBMs further includes a copper seed layer.

In operation 618 of method 600, a PCB 162 is coupled to the second RDL by the first set of UBMs.

In operation 620 of method 600, a second set of UBMs is formed on a first surface of the PCB.

In some embodiments, the second set of UBMs includes the set of solder bumps 164. In some embodiments, the first surface of the PCB includes at least surface 162a.

In some embodiments, the second set of UBMs includes at least an adhesion layer or a wetting layer. In some embodiments, the second set of UBMs includes Ti, TiN, TaN, Ta, or the like. In some embodiments, the second set of UBMs further includes a copper seed layer.

In some embodiments, one or more of operations 602, 604, 606, 608, 610, 612 or 614 of method 600 include using a combination of photolithography and material removal processes to form openings in an insulating layer (not shown) over the substrate. In some embodiments, the photolithography process includes patterning a photoresist, such as a positive photoresist or a negative photoresist. In some embodiments, the photolithography process includes forming a hard mask, an antireflective structure, or another suitable photolithography structure. In some embodiments, the material removal process includes a wet etching process, a dry etching process, an RIE process, laser drilling or another suitable etching process. The openings are then filled with conductive material, e.g., copper, aluminum, titanium, nickel, tungsten, or other suitable conductive material. In some embodiments, the openings are filled using CVD, PVD, sputtering, ALD or other suitable formation process.

In some embodiments, the conductive material includes copper, aluminum, titanium, nickel, tungsten, or other suitable conductive material. In some embodiments, the openings and trench are filled using CVD, PVD, sputtering. ALD or other suitable formation process. In some embodiments, after conductive material is deposited in one or more of operations 602, 604, 606, 608, 610, 612, 614, 616 or 620, the conductive material is planarized to provide a level surface for subsequent steps.

In some embodiments, one or more of operations 602, 604, 606, 608, 610, 612, 614, 616, 618 or 620 of method 600 is not performed.

FIGS. 7A-7B are corresponding functional flow charts of method 700 of manufacturing an IC device, in accordance with some embodiments. It is understood that additional operations may be performed before, during, and/or after at least one of method 700 depicted in FIGS. 7A-7B, and that some other processes may only be briefly described herein.

In some embodiments, method 700 is an embodiment of at least one of operation 602 or operations 606 and 608 of method 600. In some embodiments, the method 700 is usable to manufacture or fabricate at least one of integrated circuit 100A, 100B, 200, 300, 400, 500 or 800A-800K.

FIGS. 8A-8K are cross-sectional views of corresponding IC device structures 800A-800K, in accordance with some embodiments.

In some embodiments, the IC device structures 800A-800K are obtained when fabricating the first set of conductors and the second set of conductors of at least operation 602 of method 600. In some embodiments, the IC device structures 800A-800K are obtained when fabricating the set of conductors of operation 608 of method 600 or the set of conductors 140, 142 and 144 of FIG. 1A, and similar detailed description is therefore omitted.

In some embodiments, FIGS. 8A-8K are cross-sectional views of IC device structures 800A-800K that correspond to at least one of integrated circuit 100A or 100B.

In operation 702 of method 700, a first conductive material 804 is deposited on a portion of the first surface 802a of the first IC chip 802.

In some embodiments, the first conductive material 804 includes copper, aluminum, titanium, nickel, tungsten, or other suitable conductive material. In some embodiments, the first conductive material 804 is deposited using CVD, PVD, sputtering, ALD or other suitable formation process.

In the cross-sectional view of FIG. 8A, the first conductive material 804 covers a portion of the first surface 802a of the first IC chip 802.

In some embodiments, the first conductive material 804 is similar to the set of conductors 120, 122, 150 or 152, and similar detailed description is therefore omitted.

In some embodiments, the first IC chip 802 includes at least one of semiconductor die 102, 104 or 201. In some embodiments, the first IC chip 802 includes the one or more devices 136.

In operation 704 of method 700, a first insulating layer 808 and an etch stop layer (ESL) 806 are deposited on a first surface of the first conductive material 804 and the first surface 802a of the first IC chip 802.

In the cross-sectional view of FIG. 8A, the first insulating layer 808 covers a first surface of the first conductive material 804 and a portion of the first surface 802a of the first IC chip 802. In the cross-sectional view of FIG. 8A, the ESL 806 covers a first surface of the first conductive material 804 and a portion of the first surface 802a of the first IC chip 802. In the cross-sectional view of FIG. 8A, the first insulating layer 808 and the ESL 806 are arranged in an alternating manner. Other numbers of layers of the first insulating layer 808 or the ESL 806 are within the scope of the present disclosure.

In some embodiments, the first insulating layer 808 is similar to the insulating region 108, 124, 133 or 154, and similar detailed description is therefore omitted.

In some embodiments, the ESL 806 is a hard mask. In some embodiments, the hard mask includes amorphous carbon or silicon. In some embodiments, the hard mask includes silicon carbide, silicon nitride, silicon oxy-nitride, or the like. In some embodiments, the hard mask is deposited by CVD or some other deposition technique compatible with method 700. Other hard-mask materials compatible with method 700 are also included within the scope of the present disclosure. In some embodiments, after hard-mask formation, the surface of the hard mask is planarized to provide a level surface for subsequent steps.

In operation 706 of method 700, a resist material 810 is deposited on a first surface 806a of the ESL 806.

In the cross-sectional view of FIG. 8B, the resist material 810 covers the first surface 806a of the ESL 806.

In some embodiments, the resist material 810 includes a C, H or O base or the like.

In some embodiments, the resist material 810 includes a carbon-based material, a C rich base or the like.

In some embodiments, the resist material 810 includes an ash-able hard mask film or an AHM film which can be removed by O₂.

In some embodiments, the resist material 810 includes a silicon-based material, a Si base or an O base or the like.

In operation 708 of method 700, a first pillar 820a and a second pillar 820b are patterned by removing a corresponding first portion and a second portion of at least the ESL and the first insulating layer thereby forming a corresponding first opening 812a and a second opening 812b in the ESL 806 and the first insulating layer 808.

In the cross-sectional view of FIG. 8B, the resist material 810 has the first opening 812a and the second opening 812b.

In the cross-sectional view of FIG. 8C, a portion of the resist material 810 is removed.

In some embodiments, at least one of operation 708, 710 or 712 includes one or more material removal processes. In some embodiments, the material removal process includes a wet etching process, a dry etching process, an RIE process, laser drilling or another suitable etching process.

In operation 710 of method 700, a remaining portion 810a of the resist material 810 is removed from the first insulating layer 808 or the ESL 806.

In the cross-sectional view of FIG. 8D, the first insulating layer 808 and the ESL 806 are no longer covered by the remaining portion 810a of the resist material 810.

In operation 712 of method 700, a portion 806b of the ESL 806 is removed from the first insulating layer 808 and the first surface of the first conductive material 804.

In operation 714 of method 700, a barrier layer 814 is deposited in at least the first opening 812a and the second opening 812b.

In the cross-sectional view of FIG. 8E, the portion 806b of the ESL 806 is removed from the first insulating layer 808 and the first surface of the first conductive material 804. In the cross-sectional view of FIG. 8E, the barrier layer 814 covers at least the first opening 812a and the second opening 812b.

The barrier layer 814 is used to prevent the second conductive material 816 from migrating to other regions of IC 800E (e.g., the one or more device regions 102a and 104a or the one or more devices 136). In some embodiments, the barrier layer 814 includes Ta, TaN, Ti, TiN or CoW, or combinations thereof. In some embodiments, other applicable materials are used for the barrier layer 814. In some embodiments, the barrier layer 814 is formed by plating.

In operation 716 of method 700, a second conductive material 816 is deposited on the barrier layer 814 thereby filling the first opening 812a and the second opening 812b with the second conductive material 816.

In the cross-sectional view of FIG. 8F, the second conductive material 816 fills the first opening 812a and the second opening 812b. In the cross-sectional view of FIG. 8F, the second conductive material 816 covers the barrier layer 814.

In some embodiments, the second conductive material 816 includes copper, aluminum, titanium, nickel, tungsten, or other suitable conductive material. In some embodiments, the first opening 812a and the second opening 812b are filled using CVD, PVD, sputtering. ALD or other suitable formation process.

In operation 718 of method 700, a chemical mechanical polishing (CMP) process is performed to planarize a top surface 816a of the second conductive material 816.

In the cross-sectional view of FIG. 8G, the top surface 816a of the second conductive material 816 is exposed and planarized.

In some embodiments, the second conductive material 816 is planarized to provide a level surface for subsequent steps. In some embodiments, operation 718 includes a thinning process. In some embodiments, the thinning process includes at least one of a grinding operation or a polishing operation (such as chemical mechanical polishing (CMP)) or other suitable processes. In some embodiments, after the thinning process, a wet etching operation is performed to remove defects formed on the surface of IC structure 800G.

In some embodiments, method 700 is useable to manufacture a 3D-IC by bonding or by the use of one or more bump joints. For example, in some embodiments, when method 700 is useable to manufacture a 3D-IC by bonding, operation 720 is performed after operation 718. For example, in some embodiments, when method 700 is useable to manufacture a 3D-IC by the use of one or more bump joints, operations 722, 724 and 726 are performed after operation 718.

In operation 720 of method 700, a surface 850al of a first semiconductor die 850a is bonded to a surface 850b1 of a second semiconductor die 850b by a bonding layer 890.

In some embodiments, the first semiconductor die 850a corresponds to integrated circuit 800G of FIG. 8G. In some embodiments, the second semiconductor die 850b corresponds to integrated circuit 800G of FIG. 8G.

In the cross-sectional view of FIG. 8K, the surface 850al of the first semiconductor die 850a is bonded to the surface 850b1 of the second semiconductor die 850b by bonding layer 890.

In some embodiments, the first semiconductor die 850a includes at least one of the first IC chip or a second IC chip. In some embodiments, the second semiconductor die 850b includes at least one of the first IC chip or the second IC chip. In some embodiments, the second semiconductor die 850b includes the one or more devices 136. In some embodiments, the second IC chip includes the one or more devices 136. In some embodiments, the second IC chip includes at least one of semiconductor die 102, 104 or 201.

In operation 722 of method 700, a portion 808a of the first insulating layer 808 is etched thereby exposing sidewalls 822a, 822b of a first pillar 820a and a second pillar 820b.

In some embodiments, the first pillar 820a and the second pillar 820b are part of a set of pillars 820. In some embodiments, the sidewalls 822a and 822b are part of a set of sidewalls 822.

In operation 724 of method 700, a micro-bump layer 830a or 830b is formed on a surface 824 of the first pillar 820a and the second pillar 820b.

In the cross-sectional view of FIG. 8H, the sidewalls 822a, 822b of the first pillar 820a and the second pillar 820b are exposed by etching the portion 808a of the first insulating layer 808. In the cross-sectional view of FIG. 8H, the micro-bump layer 830a or 830b is on the surface 824 of the first pillar 820a and the second pillar 820b.

In some embodiments, the surface 824a of the first pillar 820a and the surface 824b of the second pillar 820b are part of a set of surfaces 824.

In some embodiments, the surface 824a of the first pillar 820a and the surface 824b of the second pillar 820b is the surface of the semiconductor die 102 and a surface of the semiconductor die 104. In some embodiments, the surface 824a of the first pillar 820a and the surface 824b of the second pillar 820b is the surface of the interconnect structure 119.

In some embodiments, a micro-bump layer 830 includes at least one of micro-bump layer 830a or 830b.

In some embodiments, the micro-bump layer 830 is the set of conductors 110, 112, 113, 140, 142, 210, 220, 310, 410, 510 or 520.

In operation 726 of method 700, the micro-bump layer 830 of a third semiconductor die 840a is coupled to the surface of a fourth semiconductor die 840b or a micro-bump layer of the fourth semiconductor die 840b by the set of bump joints 880.

In some embodiments, the third semiconductor die 840a corresponds to integrated circuit 8001 of FIG. 8I. In some embodiments, the fourth semiconductor die 840b corresponds to integrated circuit 8001 of FIG. 8I.

In some embodiments, the micro-bump layer of the fourth semiconductor die 840b is similar to the micro-bump layer 830, and similar detailed description is therefore omitted.

In the cross-sectional view of FIG. 8J, the micro-bump layer 830 of the third semiconductor die 840a is coupled to the surface of the fourth semiconductor die 840b or the micro-bump layer of the fourth semiconductor die 840b.

In some embodiments, the set of bump-joints 880 is the set of conductors 110, 112, 113, 140, 142, 210, 220, 310, 410, 510 or 520. In some embodiments, the set of bump-joints 880 is the set of conductors 114 or 144.

In some embodiments, one or more of operations 702, 704, 706, 708, 710, 712, 714, 716, 718, 720, 722, 724 or 726 of method 700 is not performed.

One aspect of this description relates to a package structure. In some embodiments, the package structure includes a first integrated circuit (IC) chip, a first set of conductors on the first IC chip, a second set of conductors on the first IC chip, a first redistribution layer coupled to the first set of conductors and the second set of conductors, and a chip layer below the first redistribution layer. In some embodiments, the chip layer includes a second IC chip electrically coupled to the first IC chip, a molding material, and a first through-via positioned in the molding material. In some embodiments, the first set of conductors is a first set of micro-bumps having a first diameter, and the second set of conductors is a second set of micro-bumps having a second diameter greater than the first diameter. In some embodiments, the first set of conductors is a first set of pillars having the first diameter, and the second set of conductors is a second set of pillars having the second diameter.

Another aspect of this description relates to a package structure. In some embodiments, the package structure includes a first integrated circuit (IC) chip, a first set of micro-bumps on the first IC chip, a second set of micro-bumps on the first IC chip, a first redistribution layer coupled to the first set of micro-bumps and the second set of micro-bumps, and a chip layer below the first redistribution layer. In some embodiments, the chip layer includes a second IC chip electrically coupled to the first IC chip, a molding material, and a first through-via positioned in the molding material. In some embodiments, the first set of micro-bumps having a first diameter and a first region. In some embodiments, the second set of micro-bumps having the first diameter and a second region. In some embodiments, the first region of the first set of micro-bumps has a first area, and a first number of micro-bumps. In some embodiments, the second region of the second set of micro-bumps has the first area, and a second number of micro-bumps greater than the first number of micro-bumps.

Still another aspect of this description relates to a method of manufacturing a package structure. In some embodiments, the method includes forming a first set of conductors and a second set of conductors on a first surface of a first integrated circuit (IC) chip, forming a first redistribution layer (RDL) on a first surface of the first set of conductors and the second set of conductors, the first RDL being coupled to the first set of conductors and the second set of conductors. In some embodiments, the method further includes forming a chip layer on a first surface of the first RDL. In some embodiments, the forming the chip layer includes coupling a second IC chip to the first surface of the RDL, forming a molding material around the second IC chip, and forming a first through-via in the molding material. In some embodiments, the second IC chip is electrically coupled to the first IC chip. In some embodiments, the first set of conductors is a first set of micro-bumps having a first diameter, and the second set of conductors is a second set of micro-bumps having a second diameter greater than the first diameter. In some embodiments, the first set of conductors is a first set of pillars having a first length, and the second set of conductors is a second set of pillars having a second length greater than the first length.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A package structure comprising:
a first integrated circuit (IC) chip;
a first set of conductors on the first IC chip;
a second set of conductors on the first IC chip;
a first redistribution layer coupled to the first set of conductors and the second set of conductors; and
a chip layer below the first redistribution layer, the chip layer comprising:
a second IC chip electrically coupled to the first IC chip;
a molding material; and
a first through-via positioned in the molding material;
wherein the first set of conductors is a first set of micro-bumps having a first diameter, and the second set of conductors is a second set of micro-bumps having a second diameter greater than the first diameter; or
the first set of conductors is a first set of pillars having the first diameter, and the second set of conductors is a second set of pillars having the second diameter.

2. The package structure of claim 1, wherein
the first set of conductors is configured to supply a set of signals to the first IC chip; and
the second set of conductors is configured to supply a supply voltage or a reference supply voltage to the first IC chip.

3. The package structure of claim 1, further comprising:
a second redistribution layer below the chip layer, wherein the chip layer is positioned between the first redistribution layer and the second redistribution layer.

4. The package structure of claim 3, further comprising:
a printed circuit board (PCB) below the second redistribution layer.

5. The package structure of claim 4, further comprising:
a first set of under-bump metallurgies (UBMs) between the PCB and the second redistribution layer.

6. The package structure of claim 5, further comprising:
a second set of UBMs positioned on a surface of the PCB.

7. The package structure of claim 1, wherein
the first set of conductors is the first set of micro-bumps;
the second set of conductors is the second set of micro-bumps; and
each micro-bump in the first set of micro-bumps is separated from an adjacent micro-bump in the first set of micro-bumps by a first pitch.

8. The package structure of claim 7, wherein the second diameter is equal to a sum of the first diameter and the first pitch.

9. The package structure of claim 1, wherein
the first set of conductors is the first set of pillars;
the second set of conductors is the second set of pillars; and
each pillar in the first set of pillars is separated from an adjacent pillar in the first set of pillars by a first pitch.

10. The package structure of claim 9, wherein the second diameter is equal to a sum of the first diameter and the first pitch.

11. The package structure of claim 1, wherein
the first set of conductors and the second set of conductors are arranged in an array including a set of rows and a set of columns, each row of the set of rows being arranged in a first direction, and each column of the set of columns being arranged in a second direction different from the first direction;
the second set of conductors is located at an intersection of a first row of the set of rows and a first column of the set of columns; and
the first set of conductors is located in a second row of the set of rows different from the first row of the set of rows, and is further located in a second column of the set of columns different from the first column of the set of columns.

12. The package structure of claim 1, wherein
the first set of conductors and the second set of conductors are arranged in an array including a set of rows and a set of columns, each row of the set of rows being arranged in a first direction, and each column of the set of columns being arranged in a second direction different from the first direction;
the second set of conductors is located in a first column of the set of columns; and
the first set of conductors is located in a sub-set of columns of the set of columns different from the first column of the set of columns.

13. A package structure comprising:
a first integrated circuit (IC) chip;
a first set of micro-bumps on the first IC chip, the first set of micro-bumps having a first diameter and a first region;
a second set of micro-bumps on the first IC chip, the second set of micro-bumps having the first diameter and a second region;
a first redistribution layer coupled to the first set of micro-bumps and the second set of micro-bumps; and
a chip layer below the first redistribution layer, the chip layer comprising:
a second IC chip electrically coupled to the first IC chip;
a molding material; and
a first through-via positioned in the molding material;
wherein the first region of the first set of micro-bumps has a first area, and a first number of micro-bumps; and
the second region of the second set of micro-bumps has the first area, and a second number of micro-bumps greater than the first number of micro-bumps.

14. The package structure of claim 13, wherein
the first set of micro-bumps is configured to supply a set of signals to the first IC chip; and
the second set of micro-bumps is configured to supply a supply voltage or a reference supply voltage to the first IC chip.

15. The package structure of claim 13, wherein
the first set of micro-bumps and the second set of micro-bumps are arranged in an array including a set of rows and a set of columns, each row of the set of rows being arranged in a first direction, and each column of the set of columns being arranged in a second direction different from the first direction;
the second set of micro-bumps is located at an intersection of a first row of the set of rows and a first column of the set of columns; and
the first set of micro-bumps is located in a second row of the set of rows different from the first row of the set of rows, and is further located in a second column of the set of columns different from the first column of the set of columns.

16. The package structure of claim 15, wherein
the first region includes a first micro-bump, a second micro-bump, a third micro-bump and a fourth micro-bump;
the second region includes a fifth micro-bump, a sixth micro-bump, a seventh micro-bump, an eighth micro-bump and a ninth micro-bump;
the first micro-bump, the second micro-bump, the fifth micro-bump, and the sixth micro-bump are aligned with each other in the first direction;
the third micro-bump, the fourth micro-bump, the seventh micro-bump, and the eighth micro-bump are aligned with each other in the first direction; and
the ninth micro-bump is located between the fifth micro-bump, the sixth micro-bump, the seventh micro-bump, and the eighth micro-bump.

17. The package structure of claim 13, wherein
the first set of micro-bumps and the second set of micro-bumps are arranged in an array including a set of rows and a set of columns, each row of the set of rows being arranged in a first direction, and each column of the set of columns being arranged in a second direction different from the first direction;
the second set of micro-bumps is located in a first column of the set of columns; and
the first set of micro-bumps is located in a sub-set of columns of the set of columns different from the first column of the set of columns.

18. The package structure of claim 17, wherein
the first region includes a first micro-bump, a second micro-bump, a third micro-bump and a fourth micro-bump;
the second region includes a fifth micro-bump, a sixth micro-bump, a seventh micro-bump, an eighth micro-bump, a ninth micro-bump and at least a portion of a tenth micro-bump;
the first micro-bump, the second micro-bump, the fifth micro-bump, and the sixth micro-bump are aligned with each other in the first direction;
the third micro-bump, the fourth micro-bump, the seventh micro-bump, and the eighth micro-bump are aligned with each other in the first direction;
the ninth micro-bump is located between the fifth micro-bump, the sixth micro-bump, the seventh micro-bump, and the eighth micro-bump; and
at least a portion of the tenth micro-bump is located along a boundary between adjacent rows of the set of rows within the first column of the set of columns.

19. A method of manufacturing a package structure comprising:
forming a first set of conductors and a second set of conductors on a first surface of a first integrated circuit (IC) chip,
forming a first redistribution layer (RDL) on a first surface of the first set of conductors and the second set of conductors, the first RDL being coupled to the first set of conductors and the second set of conductors; and
forming a chip layer on a first surface of the first RDL, the forming the chip layer comprises:
coupling a second IC chip to the first surface of the RDL, the second IC chip being electrically coupled to the first IC chip;
forming a molding material around the second IC chip; and
forming a first through-via in the molding material;
wherein the first set of conductors is a first set of micro-bumps having a first diameter, and the second set of conductors is a second set of micro-bumps having a second diameter greater than the first diameter; or
the first set of conductors is a first set of pillars having a first length, and the second set of conductors is a second set of pillars having a second length greater than the first length.

20. The method of claim 19, further comprising:
forming a second RDL on a first surface of the chip layer, wherein the chip layer is positioned between the first redistribution layer and the second RDL;
forming a first set of under-bump metallurgies (UBMs) on a first surface of the second RDL;
coupling a printed circuit board (PCB) to the second RDL by the first set of UBMs; and
forming a second set of UBMs on a first surface of the PCB.
